(19) United States
(12) Patent Application Publication
(10) Pub. No.: US 2025/0313937 A1
(43) Pub. Date: Oct. 9, 2025

(54) VAPOR DEPOSITION APPARATUS AND MANUFACTURING METHOD OF LIGHT EMITTING DEVICE

(71) Applicant: CANON KABUSHIKI KAISHA, Tokyo (JP)

(72) Inventor: YOUICHI FUKAYA, Tokyo (JP)

(21) Appl. No.: 19/090,611

(22) Filed: Mar. 26, 2025

(30) Foreign Application Priority Data
Apr. 3, 2024 (JP) 2024-060404

(51) Int. Cl. C23C 14/04; C23C 14/50; H10K 71/16

(52) U.S. Cl. CPC C23C 14/042; C23C 14/50; H10K 71/164; H10K 71/166

(57) ABSTRACT

A vapor deposition apparatus is provided. The vapor deposition apparatus includes: an electrostatic chuck table having a holding surface configured to hold a vapor deposition target substrate; and a contact portion configured to cause a mask to be in contact with the vapor deposition target substrate. The holding surface has a concave curved surface with a concave center.

### BACKGROUND OF THE INVENTION

### Field of the Invention

The present disclosure relates to a vapor deposition apparatus and a manufacturing method of a light emitting device.

### Description of the Related Art

A light emitting device including a light emitting element using an organic electroluminescence (EL) element is known. Japanese Patent Laid-Open No. 2007-119893 describes that an organic material is formed on a vapor deposition target substrate by vapor deposition using a vapor deposition device. In order to manufacture a high-resolution light emitting device, during vapor deposition using a mask, there is a need to bring the mask into tight contact with a vapor deposition target substrate or make a uniform gap between the vapor deposition target substrate and the mask. Japanese Patent Laid-Open No. 2007-119893 describes that a mask is brought into tight contact with a vapor deposition target substrate by using the magnetic force of a magnet plate to attract the mask along the vapor deposition target substrate and bend the mask and the vapor deposition target substrate toward the magnet plate side.

### SUMMARY OF THE INVENTION

To implement a high-resolution light emitting device, it is necessary to make a thin mask. In the configuration described in Japanese Patent Laid-Open No. 2007-119893, if a thin mask is used, the force of the mask for bending the vapor deposition target substrate decreases, so that the mask may not come into tight contact with the vapor deposition target substrate and a gap may be generated therebetween. In addition, if the thin mask greatly bends, the mask itself can be damaged.

Some embodiments of the present disclosure provide a technique advantageous in vapor deposition using a mask.

According to some embodiments, a vapor deposition apparatus comprising: an electrostatic chuck table having a holding surface configured to hold a vapor deposition target substrate; and a contact portion configured to cause a mask to be in contact with the vapor deposition target substrate, wherein the holding surface has a concave curved surface with a concave center, is provided.

According to some other embodiments, a manufacturing method of a light emitting device in which a plurality of pixels each including an organic layer including a light emitting layer are arranged in a substrate, the method comprising: holding the substrate on a holding surface of an electrostatic chuck table; arranging a mask to face the substrate and causing the mask to be in contact with the substrate; and vapor-depositing the organic layer on the substrate via the mask, wherein the holding surface has a concave curved surface with a concave center, is provided.

Further features of the present invention will become apparent from the following description of exemplary embodiments (with reference to the attached drawings).

### BRIEF DESCRIPTION OF THE DRAWINGS

FIG. 1 is a view showing an example of the configuration of a vapor deposition apparatus according to an embodiment;

FIGS. 2A and 2B are views showing an example of the configuration of a mask used in the vapor deposition apparatus shown in FIG. 1;

FIG. 3 is a view showing the relationship between the mask and a vapor deposition target substrate in the vapor deposition apparatus shown in FIG. 1;

FIG. 4 is a view showing an example of the configuration of a vapor deposition apparatus of a comparative example;

FIG. 5 is a view showing the relationship between a mask and a vapor deposition target substrate in the vapor deposition apparatus of the comparative example;

FIGS. 6A to 6D are views showing a manufacturing method of the mask used in the vapor deposition apparatus shown in FIG. 1;

FIGS. 7A to 7C are views showing the manufacturing method of the mask used in the vapor deposition apparatus shown in FIG. 1;

FIG. 8 is a view showing an example of the configuration of the vapor deposition apparatus according to the embodiment;

FIGS. 9A and 9B are views showing an example of the configuration of the mask used in the vapor deposition apparatus shown in FIG. 8;

FIGS. 10A and 10B are views showing an example of the configuration of the vapor deposition apparatus of a comparative example;

FIG. 11 is a view for explaining an example of the vapor deposition apparatus according to the embodiment;

FIG. 12 is a view for explaining an example of the vapor deposition apparatus according to the embodiment;

FIGS. 13A and 13B are sectional views showing an example of the configuration of a pixel of a light emitting device manufactured using the vapor deposition apparatus according to the embodiment;

FIGS. 14A to 14C are views showing an example of an image forming device using the light emitting device shown in FIGS. 13A and 13B;

FIG. 15 is a view showing an example of a display device using the light emitting device shown in FIGS. 13A and 13B;

FIG. 16 is a view showing an example of a photoelectric conversion device using the light emitting device shown in FIGS. 13A and 13B;

FIG. 17 is a view showing an example of an electronic apparatus using the light emitting device shown in FIGS. 13A and 13B;

FIGS. 18A and 18B are views each showing an example of a display device using the light emitting device shown in FIGS. 13A and 13B;

FIG. 19 is a view showing an example of an illumination device using the light emitting device shown in FIGS. 13A and 13B;

FIG. 20 is a view showing an example of a moving body using the light emitting device shown in FIGS. 13A and 13B; and

FIGS. 21A and 21B are views each showing an example of a wearable device using the light emitting device shown in FIGS. 13A and 13B.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

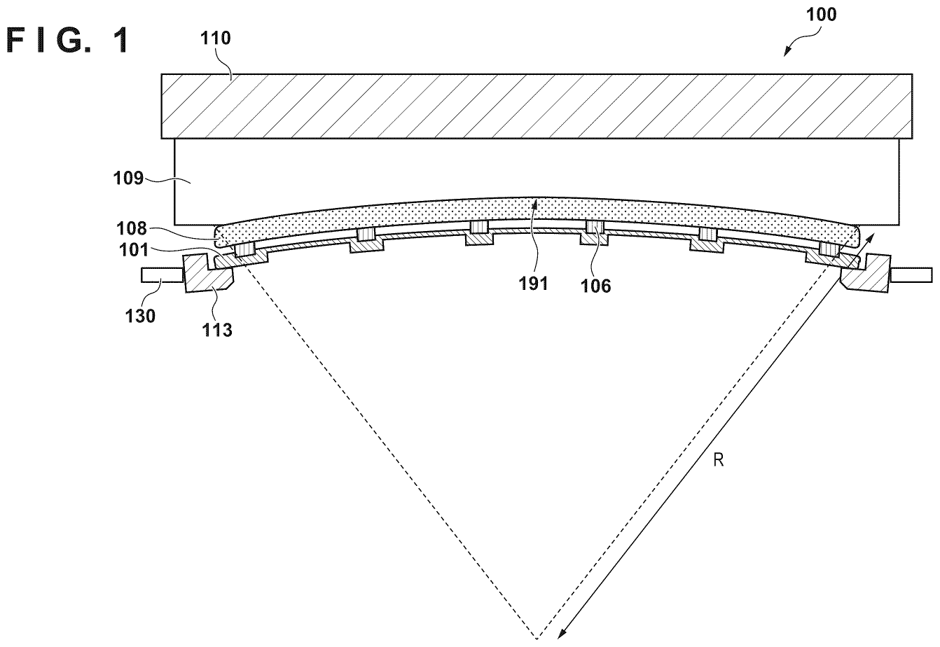

With reference to FIGS. 1 to 12, a vapor deposition apparatus according to an embodiment of the present disclosure will be described. FIG. 1 shows an example of performing vapor deposition on a vapor deposition target substrate 108 by using a vapor deposition apparatus 100 according to this embodiment. Vapor deposition using the vapor deposition apparatus 100 is used, for example, in the manufacture of a light emitting device in which a plurality of pixels each including an organic layer including a light emitting layer are arranged in a substrate. The light emitting device is, for example, an organic electroluminescence (EL) light emitting device. Here, the substrate of the light emitting device can correspond to the vapor deposition target substrate 108. Vapor deposition is used to form the organic layer including the light emitting layer. For example, in a full-color organic EL light emitting device, in order to highly accurately form fine light emitting elements of respective colors (for example, red, green, and blue), it is necessary to accurately align a high-resolution mask 101 (to be also referred to as a vapor deposition mask) on the substrate (vapor deposition target substrate 108). Furthermore, it is necessary to bring the mask 101 into tight contact with the vapor deposition target substrate 108 or make a uniform gap between the vapor deposition target substrate 108 and the mask 101.

To achieve this, the vapor deposition apparatus 100 according to this embodiment includes an electrostatic chuck table 109 having a holding surface 191 configured to hold the vapor deposition target substrate 108, and a contact portion 110 configured to cause the mask 101 to be in contact with the vapor deposition target substrate 108. Thus, the vapor deposition apparatus 100 can cause the mask 101 to face the vapor deposition target substrate 108 and perform vapor deposition. Here, the holding surface 191 of the electrostatic chuck table 109, which is configured to hold the vapor deposition target substrate 108, included in the vapor deposition apparatus 100 according to this embodiment has a concave curved surface with a concave center.

As shown in FIG. 1, the vapor deposition target substrate 108 is held by the electrostatic chuck table 109 such that the vapor deposition surface faces downward. In a sectional view in a direction intersecting the holding surface 191, the holding surface 191 of the electrostatic chuck table 109, which is configured to hold the vapor deposition target substrate 108, has an arc shape. Further, as will be described later, if each of the holding surface 191 and the mask 101 has a circular outer shape, the holding surface 191 may be a part of a spherical surface. In this case, the entire holding surface 191 of the electrostatic chuck table 109, which is configured to hold the vapor deposition target substrate 108, can be a part of the spherical surface. The holding surface 191 (arc shape or spherical surface) has a concave shape with a radius of curvature R as shown in FIG. 1. The specific radius of curvature will be described later.

The vapor deposition target substrate 108 faces the mask 101 in a concave shape with respect to the mask 101 conforming to the shape of the holding surface 191. On the side of the electrostatic chuck table 109 opposite to the vapor deposition target substrate 108, a magnet is arranged as the contact portion 110 configured to cause the mask 101 to be in contact with the vapor deposition target substrate 108. A magnetic layer 106 is arranged in the mask 101. Accordingly, it can also be said that the contact portion 110 includes a magnet that attracts the magnetic layer 106 in a direction toward the holding surface 191.

The end portion of the mask 101 is held by a mask holder 113 containing, for example, a magnetic material. A fine driving mechanism 130 is connected to the mask holder 113, so that the fine driving mechanism 130 can perform alignment between the vapor deposition target substrate 108 and the mask 101. The mask 101 is attracted together with the mask holder 113 by the magnetic force of the magnet (contact portion 110), thereby being contact with the vapor deposition target substrate 108. At that time, the mask 101 faces and is in contact with the vapor deposition target substrate 108 in a convex shape conforming to the concave shape of the vapor deposition target substrate 108.

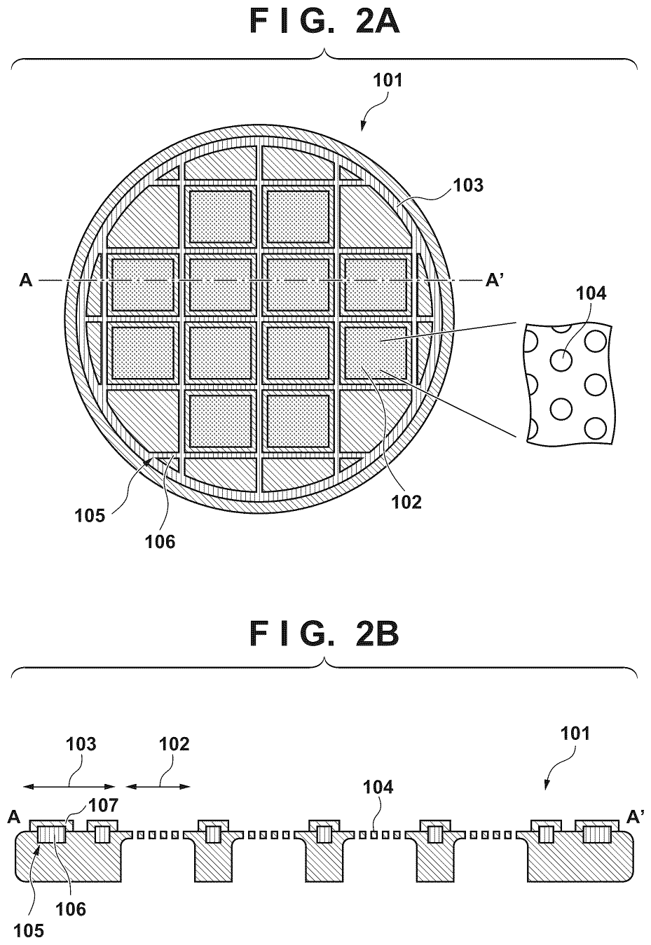

Next, the mask 101 used in the vapor deposition apparatus 100 according to this embodiment will be described. FIG. 2A is a schematic plan view of the mask 101. FIG. 2B is a schematic view showing a section taken along a line A-A′ shown in FIG. 2A. The mask 101 is provided with a region (to be referred to as a membrane region 102 hereinafter) where a plurality of opening portions 104 are arranged. During vapor deposition, a vapor deposition material passes through the opening portions 104 from a vapor deposition source, and reaches the vapor deposition target substrate 108. In order to perform vapor deposition with high accuracy and high resolution, the membrane region 102 is required to be as thin as possible. In addition, in the mask 101, a region (to be referred to as a beam region 103 hereinafter) thicker than the membrane region 102 is arranged in a grid pattern (parallel crosses pattern) to ensure the strength for the thin membrane region 102. For example, as shown in FIGS. 2A and 2B, a plurality of the membrane regions 102 are arranged, and the beam region 103 is arranged between the adjacent membrane regions 102 of the plurality of the membrane regions 102.

In the beam region 103, a concave portion 105 is provided as a groove in the grid pattern. The concave portion 105 is embedded with the magnetic layer 106 which is, for example, thicker than the depth of the concave portion 105. The mask 101 also includes a contact layer 107 that is arranged to cover the magnetic layer 106 and to be in contact with the vapor deposition target substrate 108 at the time of vapor deposition. The contact layer 107 is a layer having a lower hardness than the magnetic layer 106.

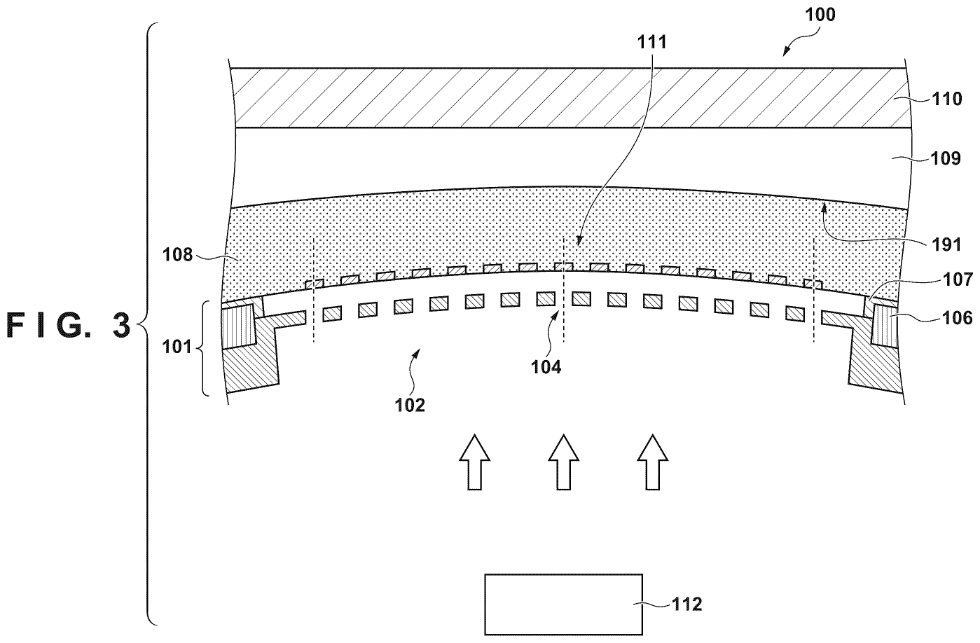

Next, with reference to FIG. 3, a state in which the mask 101 contacts with the vapor deposition target substrate 108 will be described. The opening portion 104 of the mask 101 and a vapor deposition target area 111 of the vapor deposition target substrate 108 are aligned using the fine driving mechanism 130 connected to the mask holder 113. The magnetic layer 106 is attracted to the magnet functioning as the contact portion 110 arranged on the back surface of the electrostatic chuck table 109, thereby causing the contact layer 107 of the mask 101 to be in contact with the vapor deposition target substrate 108. The contact layer 107 and the magnetic layer 106 thicker than the depth of the concave portion 105 provided in the beam region 103 also act as a spacer for preventing a direct contact between the membrane region 102 of the mask 101 and the vapor deposition target substrate 108.

In the vapor deposition apparatus 100 according to this embodiment, each of the holding surface 191 of the electrostatic chuck table 109 and the vapor deposition target substrate 108 has a concave curved surface with the radius of curvature R. Accordingly, the mask 101 being contact with the vapor deposition target substrate 108 is necessarily deformed into a convex shape with respect to the vapor deposition target substrate 108. When the mask 101 is deformed into the convex shape, a tension is applied to the membrane region 102 so that bending is less likely to occur. In other words, each membrane region 102 becomes flat. That is, when the holding surface 191 of the electrostatic chuck table 109 has a concave curved surface with the radius of curvature R, a uniform distance is maintained between the membrane region 102 of the mask 101 and the vapor deposition target substrate 108.

Here, since the radius of curvature R of the holding surface 191 is large with respect to the size of the membrane region 102, a description will be given assuming that the distance to the vapor deposition target substrate 108 is substantially constant between the central portion of the membrane region 102 and the outer edge portion thereof. Microscopically, the distance between the flat membrane region 102 and the surface of the vapor deposition target substrate 108 which becomes a curved surface conforming to the curved surface of the holding surface 191 can be different between the central portion of the membrane region 102 and the outer edge portion thereof. However, since irregular bending of the membrane region 102 as in a comparative example to be described next is suppressed, even if the distance is different between the central portion of the membrane region 102 and the outer edge portion thereof, control for forming a uniform vapor deposition film can be facilitated.

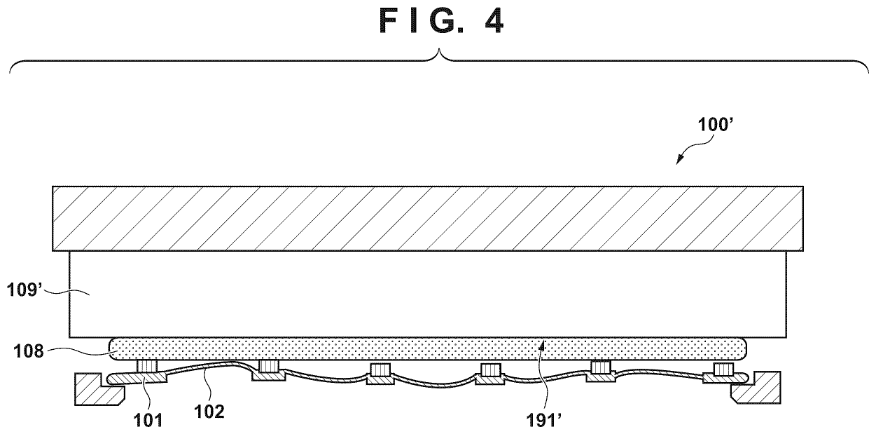

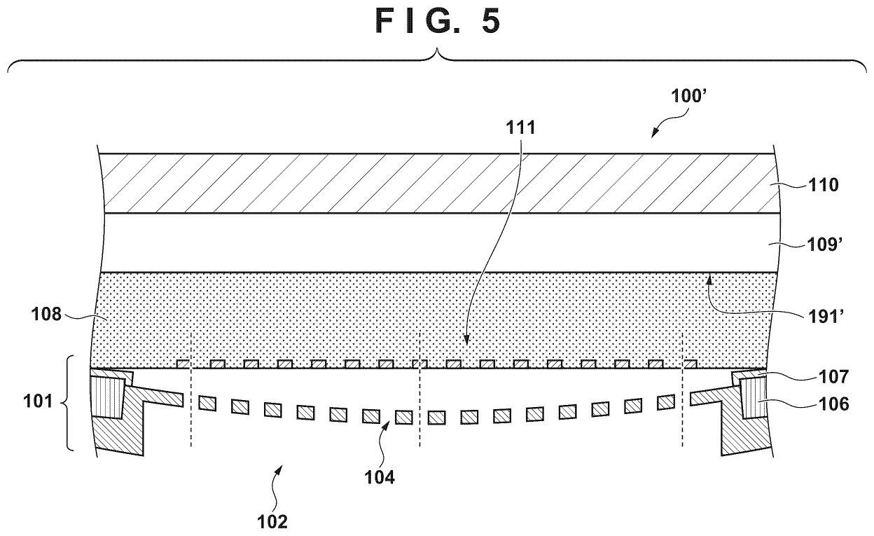

As shown in FIG. 4, consider a vapor deposition apparatus 100′ of a comparative example in which a holding surface 191′ of an electrostatic chuck table 109′ is flat. As shown in FIG. 4, in the vapor deposition apparatus 100′ of the comparative example, when the mask 101 be in contact with the vapor deposition target substrate 108, the mask 101 becomes substantially flat with respect to the vapor deposition target substrate 108 held on the flat holding surface 191′. However, in this case, the mask 101 is not completely flat but has a high-order undulation. Therefore, no tension is applied to the membrane region 102, and this causes not only bending but also variation in the bending direction depending on the location. As a result, as shown in FIG. 5, the distance between the vapor deposition target substrate 108 and the membrane region 102 of the mask 101 varies, and it is difficult to form a uniform vapor deposition film in the vapor deposition target area 111 with high alignment accuracy.

On the other hand, in this embodiment, the mask 101 bends into a convex shape with respect to the vapor deposition target substrate 108. Accordingly, a tension is applied to the membrane region 102 so that the distance between the membrane region 102 and the vapor deposition target substrate 108 is maintained uniform. Hence, according to the vapor deposition apparatus 100 described in this embodiment, it is possible to form a uniform vapor deposition film in the vapor deposition target area 111 with high alignment accuracy.

Next, the membrane region 102 and beam region 103 of the mask 101 used in the vapor deposition apparatus 100 according to this embodiment will be further described. The membrane region 102 needs to be held in a flat state as described above. Therefore, the membrane region 102 may be formed of a nonmagnetic material having a volume magnetic susceptibility of 1 or less, which is not easily deformed due to the magnetic field from the magnet functioning as the contact portion 110 for causing the contact layer 107 of the mask 101 to be in contact with the vapor deposition target substrate 108. Further, the material forming the membrane region 102 may be a material that is difficult to deform. For example, the membrane region 102 may be selected from high-rigidity materials having a Young's modulus of 50 GPa or more. Furthermore, the membrane region may be formed of a material having a Young's modulus of over 100 GPa. The membrane region 102 may be configured to have a film structure that exerts a tensile stress as a whole. The tensile stress imparted to the membrane region 102 helps the membrane region 102 to remain flat. Furthermore, since the opening portions 104 need to be provided with high accuracy and high resolution, the material forming the membrane region 102 can be selected from materials that can be processed with high accuracy and high resolution.

The beam region 103 can be a region that decides the rigidity and weight of the entire mask 101. Therefore, the beam region 103 may be formed of a material having a similar rigidity but a lower specific gravity than the membrane region 102. Furthermore, when the beam region 103 is formed of a material having a small linear expansion coefficient or a linear expansion coefficient similar to that of the vapor deposition target substrate 108, misalignment between the mask 101 and the vapor deposition target substrate 108 caused by heat generation during vapor deposition can be suppressed.

The magnetic layer 106 can be formed of a material that is easily attracted by the magnet (contact portion 110). Accordingly, a material having a volume magnetic susceptibility of 10 or more may be selected for the magnetic layer 106. Further, a material having a volume magnetic susceptibility of 100 or more may be selected for the magnetic layer 106. More specifically, iron, nickel, cobalt, an alloy thereof, and the like can be selected for the magnetic layer 106. Here, the above-described value of the volume magnetic susceptibility is a value in the SI unit system.

The contact layer 107 is a portion of the mask 101 that directly be in contact with the vapor deposition target substrate 108. Therefore, the contact layer 107 is required not to damage the vapor deposition target substrate 108. Accordingly, a material having a lower hardness than the materials forming the base material of the mask 101 and the magnetic layer 106 can be selected as the material forming the contact layer.

Next, the vapor deposition target substrate 108 used in the vapor deposition apparatus 100 according to this embodiment will be described. As the vapor deposition target substrate 108, a silicon wafer, a glass substrate, or the like can be used. The holding surface 191 of the electrostatic chuck table 109 of the vapor deposition apparatus 100 according to this embodiment has a concave curved surface with respect to the vapor deposition target substrate 108. Therefore, in order to be easily held on the holding surface 191, the vapor deposition target substrate 108 may bend into a convex shape with respect to the holding surface 191. Bending of the vapor deposition target substrate 108 may be achieved by forming a film that imparts a compressive stress to the main surface of the vapor deposition target substrate 108, of two main surfaces of the vapor deposition target substrate 108, on the side to be held by the electrostatic chuck table 109. Alternatively, bending of the vapor deposition target substrate 108 may be achieved by forming a film that imparts a tensile stress to the main surface, of two main surfaces of the vapor deposition target substrate 108, on the vapor deposition target area 111 side.

Next, the electrostatic chuck table 109 will be described. The electrostatic chuck table 109 is generally formed of a ceramic material having substantially the same outer diameter as the vapor deposition target substrate 108, and an internal electrode is formed in the ceramic. By applying a voltage to the internal electrode, a Coulomb force or a Johnsen-Rahbek force is generated between the electrostatic chuck table 109 and the vapor deposition target substrate 108, thereby making it possible to hold the vapor deposition target substrate 108. In this embodiment, the holding surface 191 of the electrostatic chuck table 109 is processed to have the concave curved surface with the radius of curvature R. Accordingly, the distance between the central portion of the holding surface 191 and the vapor deposition target substrate 108 tends to be large. Therefore, a Johnsen-Rahbek force type electrostatic chuck having a high attractive force may be selected as the electrostatic chuck table 109.

Furthermore, the electrostatic chuck table 109 may be configured such that the force per unit area for attracting the vapor deposition target substrate 108 is greater in the central portion of the holding surface 191 than in the outer edge portion thereof. For example, the internal electrode arranged in the ceramic may be configured to apply a higher voltage to the central portion of the holding surface 191. Alternatively, for example, the ceramic materials and its configuration may be adjusted such that the ceramic in the central portion of the holding surface 191 has a higher conductivity than the ceramic in the outer edge portion.

In the vapor deposition apparatus 100 according to this embodiment, the reason why the holding surface 191 of the electrostatic chuck table 109 has the concave curved surface is, as described above, to bend the mask 101 into the convex shape conforming to the radius of curvature R, thereby applying a tension to the membrane region 102. Here, for bending the mask 101 into the convex shape, the radius of curvature R needs to be controlled accurately. This is because, if the radius of curvature R is too large, a sufficient tension may not be applied to the membrane region 102 of the mask 101. If the radius of curvature R is too small, an excessive stress is applied to the mask 101 (for example, the membrane region 102 and the like), and this may cause damage, plastic deformation, or the like.

On the other hand, the convex shape of the mask 101 during vapor deposition is uniquely decided by the radius of curvature R of the holding surface 191. Since the holding surface 191 is formed of a high-rigidity ceramic material, the radius of curvature R of the holding surface 191 is always kept constant regardless of holding of the vapor deposition target substrate 108 and contact of the mask 101. That is, the electrostatic chuck table 109 of the vapor deposition apparatus 100 according to this embodiment can control the convex shape of the mask 101 to be always constant, so that a sufficient tension can be applied to the membrane region 102 without causing damage or plastic deformation.

The magnet functioning as the contact portion 110 is a member for attracting the mask 101 and the mask holder 113 to the side of the electrostatic chuck table 109 and the vapor deposition target substrate 108. For example, a mechanism for operation in the vertical direction in FIG. 1 intersecting the holding surface 191 is connected to the magnet (contact portion 110). With this, the magnet (contact portion 110) can be moved close to or away from the electrostatic chuck table 109. In a state in which the mask 101 and the mask holder 113 are close to the vapor deposition target substrate 108, the magnet functioning as the contact portion 110 is brought close to (for example, in contact with) the electrostatic chuck table 109. Thus, the mask holder 113 and the mask 101 are attracted to the vapor deposition target substrate 108 side due to the magnetic force of the magnet (contact portion 110), and the mask 101 is in contact with the vapor deposition target substrate 108.

The mask holder 113 fixes the mask 101, and also has a role of, when receiving a magnetic force from the magnet (contact portion 110), reliably causing the outer edge of the mask 101 to be in contact with the outer edge of the vapor deposition target substrate 108. Accordingly, the mask holder 113 may be formed of a material having a volume magnetic susceptibility of 100 or more. More specifically, iron, nickel, cobalt, an alloy thereof, and the like can be selected for the mask holder 113. The fine driving mechanism 130 can be connected to the mask holder 113 to enable alignment between the mask 101 and the vapor deposition target substrate 108.

The vapor deposition apparatus 100 according to this embodiment configured as described above can implement uniform contact between the mask 101 and the vapor deposition target substrate 108 without breaking the mask 101. That is, it is possible to increase the resolution and, further, improve the reliability of the organic electronic device such as a light emitting device manufactured using the vapor deposition apparatus 100 according to this embodiment.

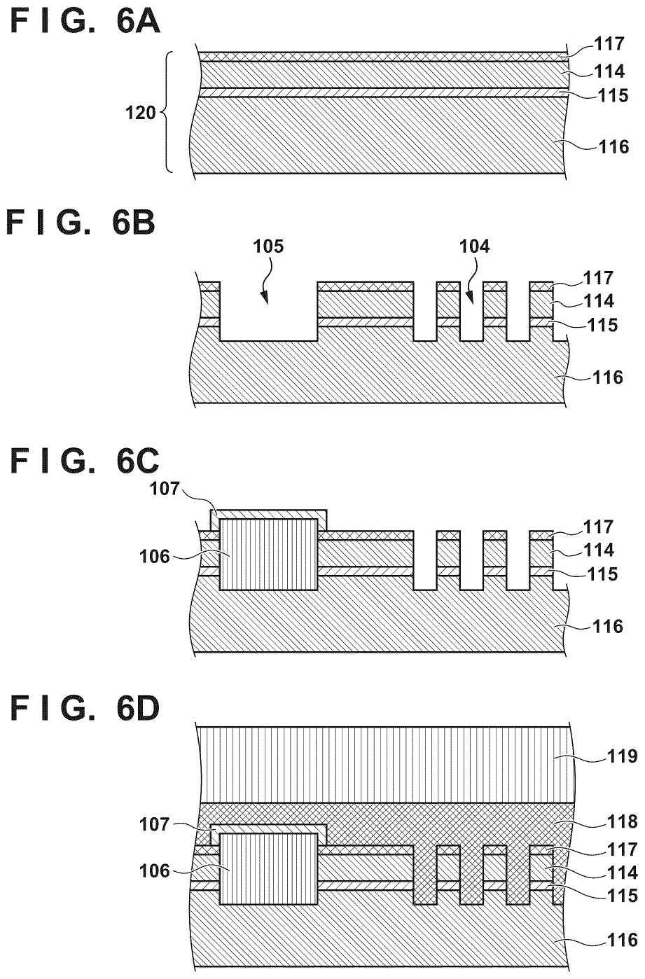

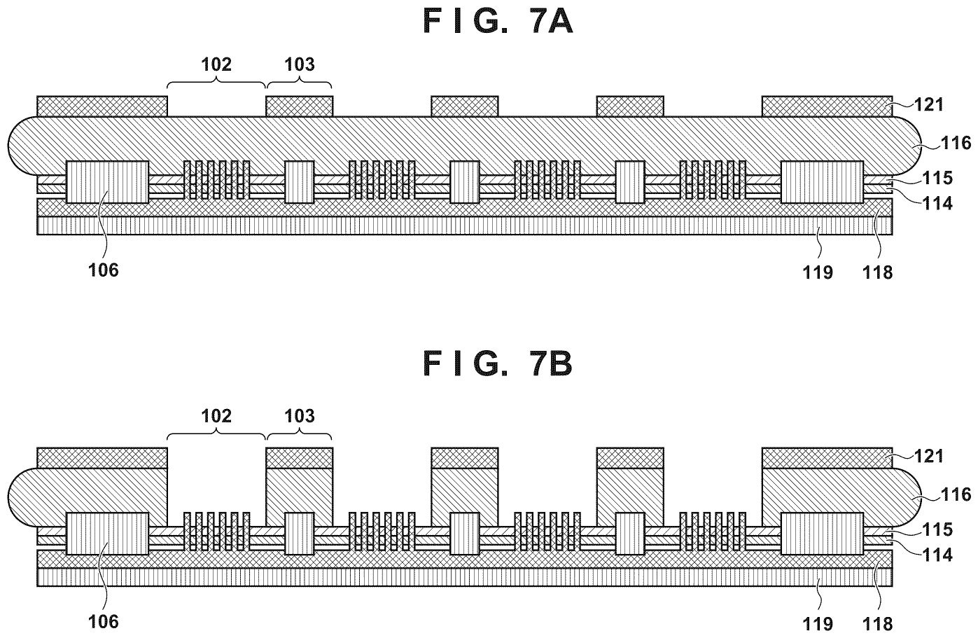

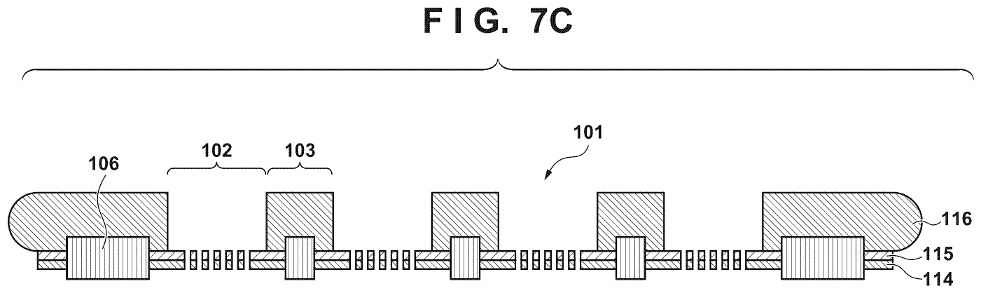

Next, examples of this embodiment will be described. First, an example of a manufacturing method of the mask 101 will be described with reference to FIGS. 6A to 7C.

As the base material of the mask 101, a Silicon On Insulator (SOI) substrate containing silicon was used. In this example, a device layer 114 of the SOI substrate 120 is the main constituent material of the membrane region 102. Therefore, the film thickness of the device layer 114 of the SOI substrate 120 is set larger than that of a box layer 115. The device layer 114 is a layer made of single-crystal silicon with a high Young's modulus and a low specific gravity, which is easy to microfabricate, so that it is suitable as the constituent material of the membrane region 102. The Young's modulus and indentation hardness of the device layer 114 were measured by a nanoindentation method and found to be 135 GPa and 11.3 GPa, respectively. The thickness of the device layer 114 was set to 3.0 μm.

First, as shown in FIG. 6A, silicon nitride was deposited as a stress adjustment layer 117 on the surface of the device layer 114 of the SOI substrate 120. Silicon nitride can be formed using, for example, a plasma CVD method or the like. The stress adjustment layer 117 makes it possible to impart a tensile stress to the device layer 114 (and the box layer 115) serving as the base material of the mask 101. As a result, when performing vapor deposition in the vapor deposition apparatus 100 using the completed mask 101, the membrane region 102 readily remains flat. In this example, the film stress applied by the stress adjustment layer 117 to the device layer 114 (and the box layer 115) is a tensile stress of 150 MPa. The Young's modulus and indentation hardness of the stress adjustment layer 117 were 140 GPa and 7.5 GPa, respectively.

After the stress adjustment layer 117 was formed, the concave portion 105 and the opening portions 104 were patterned as shown in FIG. 6B by using a photolithography method or various kinds of etching methods. For example, Reactive Ion Etching (RIE) using a reactive gas was used to etch, in addition to the stress adjustment layer 117 and the device layer 114, the box layer 115 and a part of a handle layer 116.

Then, a seed layer was formed in the concave portion 105, and the magnetic layer 106 using nickel was formed by electroplating until it was 1.0 μm thicker than the concave portion 105. Here, the indentation hardness of the magnetic layer 106 using nickel was 6.1 GPa. After the magnetic layer 106 was formed, the magnetic layer 106 was subjected to electroless nickel and polytetrafluoroethylene (PTFE) composite plating to form the contact layer 107 as shown in FIG. 6C. The film thickness and indentation hardness of the contact layer 107 were 1.0 μm and 2.6 GPa, respectively. In this example, a nickel and polytetrafluoroethylene (PTFE) composite was used as the contact layer 107. However, the present invention is not limited to this, and any material may be selected that has a lower hardness than the materials forming the base material of the mask 101 and the magnetic layer 106. For example, parylene resin, polyimide resin, acrylic resin, or the like may be used as the contact layer 107.

After the contact layer 107 was formed, a resist was spray-coated by an air spray method so as to cover the entire surface of the SOI substrate 120 on the device layer 114 side, thereby forming a protection layer 118. Furthermore, as shown in FIG. 6D, a conductive tape 119 was attached so as to cover the protection layer 118.

Then, the SOI substrate 120 with the conductive tape 119 attached thereto was subjected to processing on the handle layer 116 side. First, as shown in FIG. 7A, a resist pattern 121 was formed, using a photolithography method or the like, on the surface of the handle layer 116 in a region to be the beam region 103 of the mask 101. The opening portions in the resist pattern 121 become the membrane regions 102.

After the resist pattern 121 was formed, the handle layer 116 was etched up to the box layer 115, as shown in FIG. 7B. The handle layer 116 was etched using a Bosch method.

Subsequently, the conductive tape 119 was peeled off from the SOI substrate 120, and the resist pattern 121 and the protection layer 118 were stripped with an organic solvent. Thus, the mask 101 shown in FIG. 7C was obtained.

The thus obtained mask 101 according to the example of this embodiment is processed using a silicon process, so that it can have a high resolution. On the other hand, the membrane region 102 is mainly constituted by a single-crystal silicon film as thin as 3.0 μm. Therefore, although the rigidity is high, it is bent by 3.0 μm or more in the convex or concave direction, and a crack can easily occur particularly in the crystal orientation.

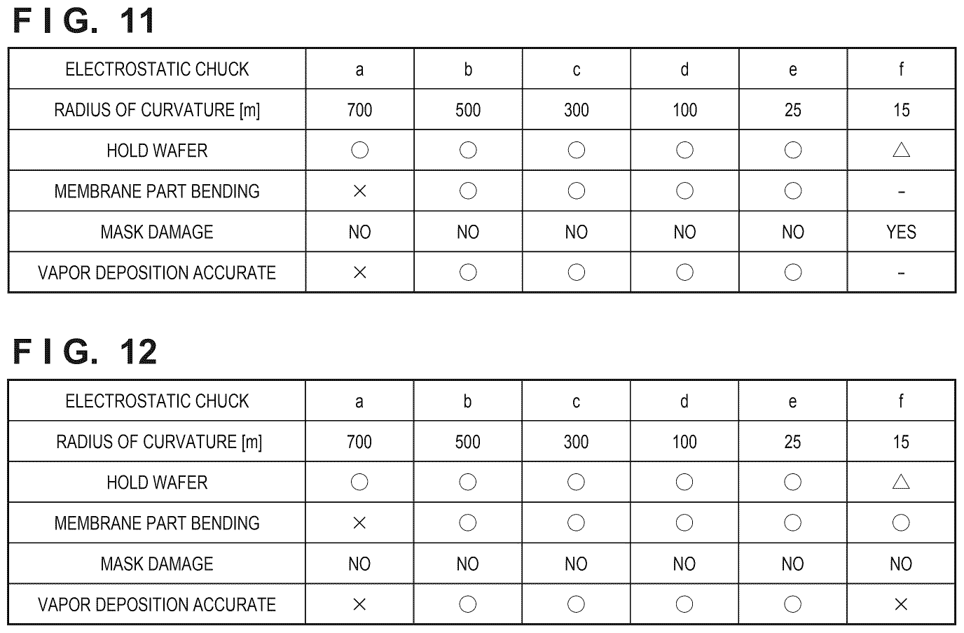

Next, vapor deposition was attempted on a silicon wafer serving as the vapor deposition target substrate 108 by using the obtained vapor deposition mask 101. At this time, the radius of curvature R of the holding surface 191 of the electrostatic chuck table 109 was changed from 15 m to 700 m for comparison. The comparison results are shown in FIG. 11.

First, an evaluation was made as to whether the holding surface 191 of the electrostatic chuck table 109 having a concave curved surface could hold the vapor deposition target substrate 108 using a silicon wafer. As a result, there were some cases where an electrostatic chuck f having the holding surface 191 with the radius of curvature of less than 25 mm could not hold the silicon wafer. Hence, in FIG. 11, the item of wafer holding for the electrostatic chuck f is marked with “A”. On the other hand, electrostatic chucks a to e each having the holding surface 191 of the electrostatic chuck table 109 with the radius of curvature R of 25 m or more and 700 m or less could hold the silicon wafer.

Next, an evaluation was made as to whether bending of the membrane region 102 was eliminated while the mask 101 was in contact with the silicon wafer serving as the vapor deposition target substrate 108. A laser displacement gauge was used to evaluate the bending.

The mask 101 was scanned with the laser displacement gauge in the diameter direction to obtain the profile of the membrane region 102. If the profile of the membrane region 102 could be fitted to the radius of curvature R of the holding surface 191 of the electrostatic chuck table 109 within a range of ±1 μm, it was determined to be accepted. In FIG. 11, “accepted” is indicated by “o”. If the profile of the membrane region 102 could not be fitted, it was determined to be rejected. In FIG. 11, “rejected” is indicated by “x”.

As a result, in the electrostatic chuck a with the radius of curvature R of over 500 m, the bending of the membrane region 102 of the mask 101 was not eliminated. On the other hand, in the electrostatic chucks b to f with the radius of curvature R of 500 m or less, it was confirmed that the bending of the membrane region 102 of the mask 101 was eliminated. However, in the electrostatic chuck f with the radius of curvature of less than 25 m, damage to the membrane region 102 occurred, which was thought to be caused by a stress generated when the mask 101 was deformed into a convex shape to cause the mask 101 to be in contact with the silicon wafer.

Next, vapor deposition was performed on the silicon wafer using the mask 101 by using each of the electrostatic chucks b, c, d, and e with the radius of curvature R in the range of 25 to 500 m. As a result, it was confirmed that a vapor deposition film having a desired profile was formed at a desired position. Therefore, in the vapor deposition apparatus 100 according to this embodiment, it was found that when the holding surface 191 of the electrostatic chuck table 109 has the radius of curvature R of 25 m or more and 500 m or less, a vapor deposition film can be formed with high resolution and high accuracy.

In the example described above, a silicon wafer was used as the vapor deposition target substrate 108. In addition, the SOI substrate 120 was used as the base material of the mask 101. Therefore, each of the mask 101 and the holding surface 191 may have a circular outer shape. Here, the circular outer shape of the holding surface 191 means that the holding surface 191 is circular in a planar view with respect to the holding surface 191. For the mask 101, the surface where the opening portions 104 for passing through the deposition material are arranged can be circular, as shown in FIG. 2A. In this case, the holding surface 191 may be a part of a cylindrical shape whose sections have the same arc shape along one direction. Alternatively, for example, when each of the mask 101 and the holding surface 191 has a circular outer shape, the holding surface 191 may be a part of a spherical surface.

The example has been described in which the SOI substrate 120 is used as the base material of the mask 101, but the present invention is not limited to this. For example, as described above, another material may be used as long as the membrane region 102 of the mask 101 is formed of a nonmagnetic material having a volume magnetic susceptibility of 1 or less. For example, a glass substrate made of quartz or the like, a ceramic substrate, or the like may be used as the base material of the mask 101. In addition, the vapor deposition target substrate 108 is not limited to a silicon wafer. For example, a glass substrate made of quartz or the like, a ceramic substrate, or the like may be used as the vapor deposition target substrate 108.

In the above-described embodiment and example, it has been described that the magnetic layer 106 is arranged in the mask 101 and the magnet is arranged as the contact portion 110. However, the present invention is not limited to this. As the contact portion 110, for example, a jig that presses one main surface, of two main surfaces of the mask 101, opposite to the other main surface facing the vapor deposition target substrate 108 may be used, without arranging the magnetic layer 106 in the mask 101. In this case, for example, the jig may push the beam region 103 of the mask 101 toward the vapor deposition target substrate 108, may be provided with an opening portion for passing through a vapor deposition material at a position corresponding to the membrane region 102 of the mask 101. The portion of the jig to press the mask 101 may have a shape corresponding to the concave curved surface of the holding surface 191 of the electrostatic chuck table 109. For example, the portion of the jig to press the mask 101 may have a convex curved surface in the direction toward the mask 101. With this, the jig functioning as the contact portion 110 can cause the contact layer 107 in the beam region 103 of the mask 101 to be in contact with the vapor deposition target substrate 108, and apply a tension as described above to the membrane region 102.

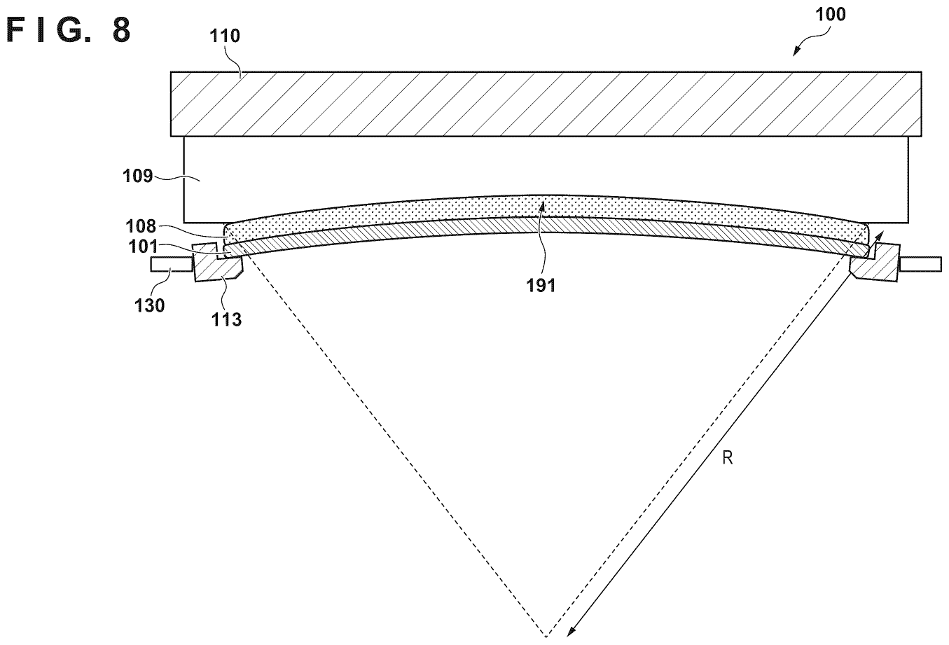

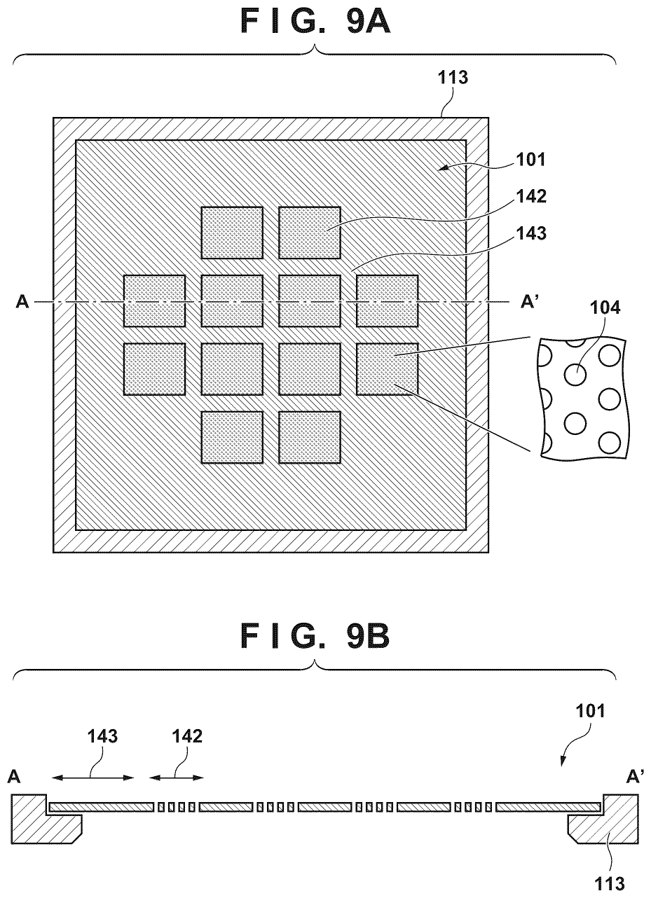

Next, a modification of the above-described vapor deposition apparatus 100 will be described with reference to FIGS. 8 to 9B. In the configuration shown in FIGS. 8 to 9B, the mask 101 is different from the above-described embodiment. The configuration different from the above-described embodiment will mainly be described below, and a description of the configuration that may be similar to the above-described embodiment will be omitted, as appropriate.

FIG. 8 is a view for explaining a contact mechanism between the mask 101 and the vapor deposition target substrate 108 in this embodiment. In this embodiment, the mask 101 is formed of a magnetic material, unlike the above-described configuration in which silicon (SOI substrate 120) is used as the base material. Accordingly, the entire surface of the mask 101 is in contact with the vapor deposition target substrate 108 due to the magnetic force from the magnet functioning as the contact portion 110. Here, in FIG. 8, similarly to FIG. 1, details of the opening portions 104 of the mask 101 and the like are omitted. The configuration of the vapor deposition apparatus and that of the mask 101 can be similar to those shown in FIG. 3.

Next, the mask 101 used in this embodiment will be described. FIG. 9A is a schematic plan view of the mask 101 in this embodiment. FIG. 9B is a schematic view showing a section taken along a line A-A′ in FIG. 9A.

The mask 101 is provided with a region 142 having the plurality of opening portions 104. During vapor deposition, a vapor deposition material passes through the opening portions 104 from a vapor deposition source, and reaches the vapor deposition target substrate 108. The mask 101 is also provided with a region 143 in a grid pattern where no opening portion 104 is arranged. In this embodiment, the thickness of the region 142 where the opening portions 104 are arranged and the thickness of the region 143 where no opening portion 104 is arranged are equal. As described above, in order to perform vapor deposition with high accuracy and high resolution, the region 142 is required to be as thin as possible. That is, in the configuration shown in FIGS. 9A and 9B, the thickness of the mask 101 itself is required to be as small as possible. Therefore, the mask 101 according to this embodiment is in the form of a thin sheet as a whole.

When performing vapor deposition, the end portion of the mask 101 is fixed by the mask holder 113. In this embodiment, both the mask 101 and the mask holder 113 can be formed of a magnetic material. Hence, the mask 101 and the mask holder 113 may be integrally formed. More specifically, iron, nickel, cobalt, an alloy thereof, and the like can be selected as the magnetic material used for the mask 101 and the mask holder 113.

In the vapor deposition apparatus 100 according to this embodiment, each of the holding surface 191 of the electrostatic chuck table 109 and the vapor deposition target substrate 108 conforming to the holding surface 191 have concave curved surface with the radius of curvature R, as described above. Accordingly, the mask 101 being contact with the vapor deposition target substrate 108 is necessarily deformed into a convex shape with respect to the vapor deposition target substrate 108. When the mask 101 is deformed into the convex shape, a tension is applied to the entire mask 101 so that bending is less likely to occur. That is, when the holding surface 191 of the electrostatic chuck table 109 has a concave shape with the radius of curvature R, it is easier for the mask 101 and the vapor deposition target substrate 108 to completely contact with each other.

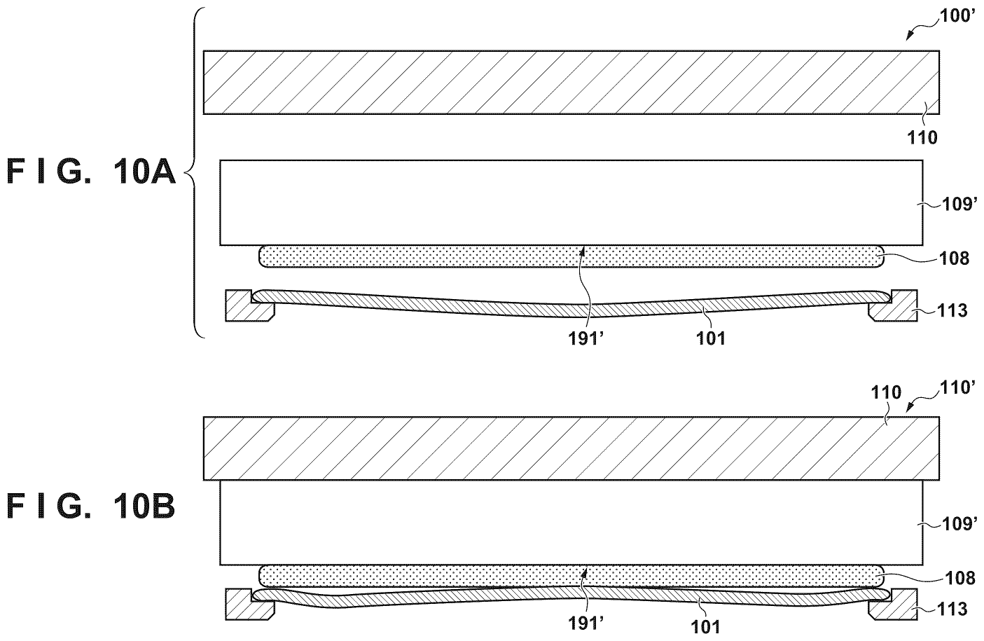

Here, consider the vapor deposition apparatus 100′ of a comparative example in which the holding surface 191′ of the electrostatic chuck table 109′ is flat as shown in FIGS. 10A and 10B. Since the mask 101 according to this embodiment is in the form of a thin sheet, it easily bends due to its own weight. Therefore, as shown in FIG. 10A, when the magnet (contact portion 110) is away from the electrostatic chuck table 109, the mask 101 bends into a concave shape relative to the vapor deposition target substrate 108. Thereafter, when the magnet approaches (abuts) the electrostatic chuck table 109, a magnetic force is applied to the mask 101 and the mask holder 113, so that the mask 101 is in contact with the vapor deposition target substrate 108.

At this time, since the mask holder 113 having the large volume of the magnetic body is most susceptible to the magnetic force, the end portion side of the mask 101 first is in contact with the vapor deposition target substrate 108. Almost simultaneously with the contact of the end portion of the mask 101 with the vapor deposition target substrate 108, the central portion of the mask 101, which is most easily displaced, contacts with the vapor deposition target substrate 108. Hence, the region of the mask 101 other than the end portion and the central portion sequentially is in contact with the vapor deposition target substrate 108 while the positions of the end portion and the central portion are fixed. As a result, as shown in FIG. 10B, a gap between the vapor deposition target substrate 108 and the mask 101 is easily generated between the end portion and the central portion of the mask 101. If vapor deposition is performed in the state shown in FIG. 10B, the distance between the mask 101 and the vapor deposition target substrate 108 varies, and it is difficult to form a uniform film on the vapor deposition target substrate 108 with high alignment accuracy.

On the other hand, in this embodiment, the holding surface 191 of the electrostatic chuck table 109 has the concave shape with respect to the mask 101, and the distance between the mask 101 and the vapor deposition target substrate 108 increases toward the central portion. Hence, when the mask 101 is in contact with the vapor deposition target substrate 108, it is difficult for the central portion of the mask 101 to first is in contact with the vapor deposition target substrate 108. That is, the mask 101 sequentially is in contact with the vapor deposition target substrate 108 while a tension is applied from the end portion of the mask 101 toward the center. As a result, it is possible to cause the mask 101 to be in contact with the vapor deposition target substrate 108 without any gap. Therefore, a uniform film can be formed on the vapor deposition target substrate 108 with high alignment accuracy.

Next, an example of this embodiment in which a magnetic material is used as the mask 101 will be described. Invar was used as the base material of the mask 101. The mask 101 was manufactured by electroforming, and the thickness of the invar was set to 10 μm. Next, vapor deposition was attempted on a silicon wafer serving as the vapor deposition target substrate 108 by using the obtained vapor deposition mask 101. At this time, the same electrostatic chucks a to f as in the above-described example were used to perform similar comparison. The comparison results are shown in FIG. 12.

The evaluations as to holding of the silicon wafer serving as the vapor deposition target substrate 108 are the same as in the above-described example. Next, an evaluation was made, using a laser displacement gauge, as to whether the mask 101 is in contact with the silicon wafer serving as the vapor deposition target substrate 108. The entire surface of the mask 101 in contact with the silicon wafer was scanned by the laser displacement gauge to obtain the profile of the mask 101. If the planar profile of the mask 101 could be fitted to the radius of curvature R of the holding surface 191 of the electrostatic chuck table 109 within a range of ±1 μm, it was determined to be acceptable. In FIG. 12, “accepted” is indicated by “o”. If the planar profile of the mask 101 could not be fitted, it was determined to be rejected. In FIG. 12, “rejected” is indicated by “x”.

As a result, in the electrostatic chuck a with a radius of curvature of over 500 m, a part of the mask 101 was not in contact with the silicon wafer serving as the vapor deposition target substrate 108. On the other hand, in the electrostatic chucks b to f with a radius of curvature of 500 m or less, it was confirmed that the entire surface of the mask 101 was in contact with the silicon wafer. No damage to the mask 101 was observed in all the electrostatic chucks a to f. However, when vapor deposition was performed on the silicon wafer serving as the vapor deposition target substrate 108, a deviation of the film formation position was confirmed on the silicon wafer on which a film was formed using the electrostatic chuck f with the radius of curvature of less than 25 m. It was inferred that this deviation of the film formation position occurred because the mask 101 of this example was plastically deformed due to a stress generated when it was deformed into a convex shape. On the other hand, in vapor deposition using each of the electrostatic chucks b, c, d, and e with the radius of curvature R in the range of 25 to 500 m, it was confirmed that a vapor deposition film having a desired profile was formed at a desired position. Therefore, also in this example, it was found that when the holding surface 191 of the electrostatic chuck table 109 has the radius of curvature R of 25 m or more and 500 m or less, a vapor deposition film can be formed with high resolution and high accuracy.

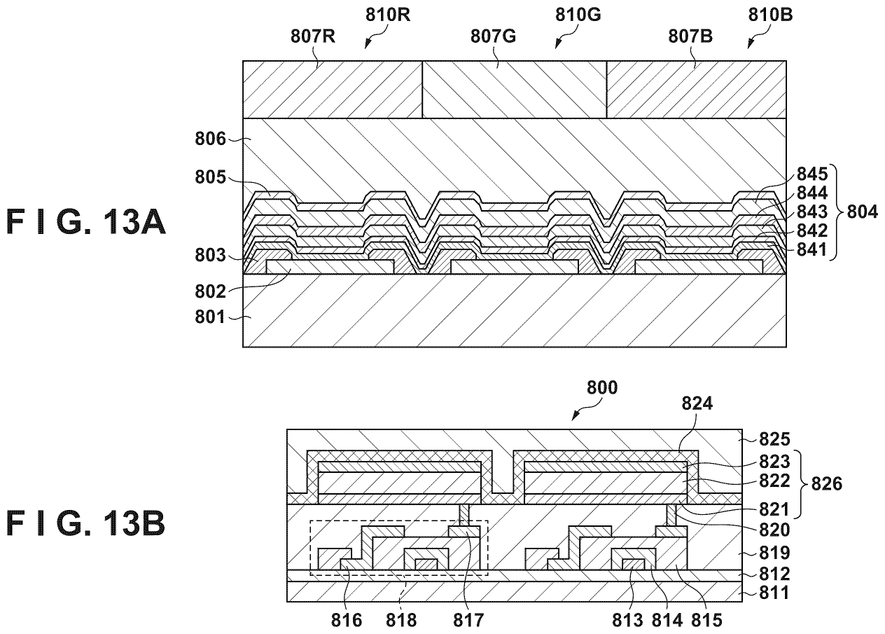

Here, a light emitting device that includes a pixel (light emitting element) including an organic layer such as a light emitting layer, which is formed using the vapor deposition apparatus 100 and mask 101 according to this embodiment, will be described. Furthermore, application examples in which such the light emitting device is applied to an image forming device, a display device, a photoelectric conversion device, an electronic apparatus, an illumination device, a moving body, and a wearable device will be described with reference to FIGS. 13A to 21B. The description will be given assuming that, for example, an organic light emitting element (OLED) such as an organic EL element using an organic light emitting material is arranged in the pixel (to be sometimes referred to as the light emitting element, the sub-pixel, or the like) arranged in the light emitting device. Details of each component arranged in the pixel of the light emitting device will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

If the organic compound according to this embodiment is contained in the light emitting layer, the light emitting layer may be a layer made of only the organic compound according to this embodiment or a layer made of the organic metal complex according to this embodiment and another compound. Here, if the light emitting layer is a layer made of the organic metal complex according to this embodiment and another compound, the organic compound according to this embodiment may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. Note that the assist material is also called a second host. The host material can be called a first compound, and the assist material as a second compound.

If the organic compound according to an embodiment of the present disclosure is used as the guest of the light emitting layer, the concentration of the guest may be 0.01 mass % (inclusive) to 20 mass % (inclusive) relative to the entire light emitting layer, or may be 0.1 mass % (inclusive) to 10 mass % (inclusive). The guest is also called a dopant.

The organic metal complex according to this embodiment can be used as the constituent material of the organic compound layer other than the light emitting layer forming the organic light emitting element according to this embodiment. More specifically, the organic metal complex may be used as the constituent material of an electron transport layer, an electron injection layer, a hole transport layer, a hole injection layer, a hole blocking layer, or the like. In this case, the light emission color of the organic light emitting element is not limited to red. More specifically, it may be white or an intermediate color.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

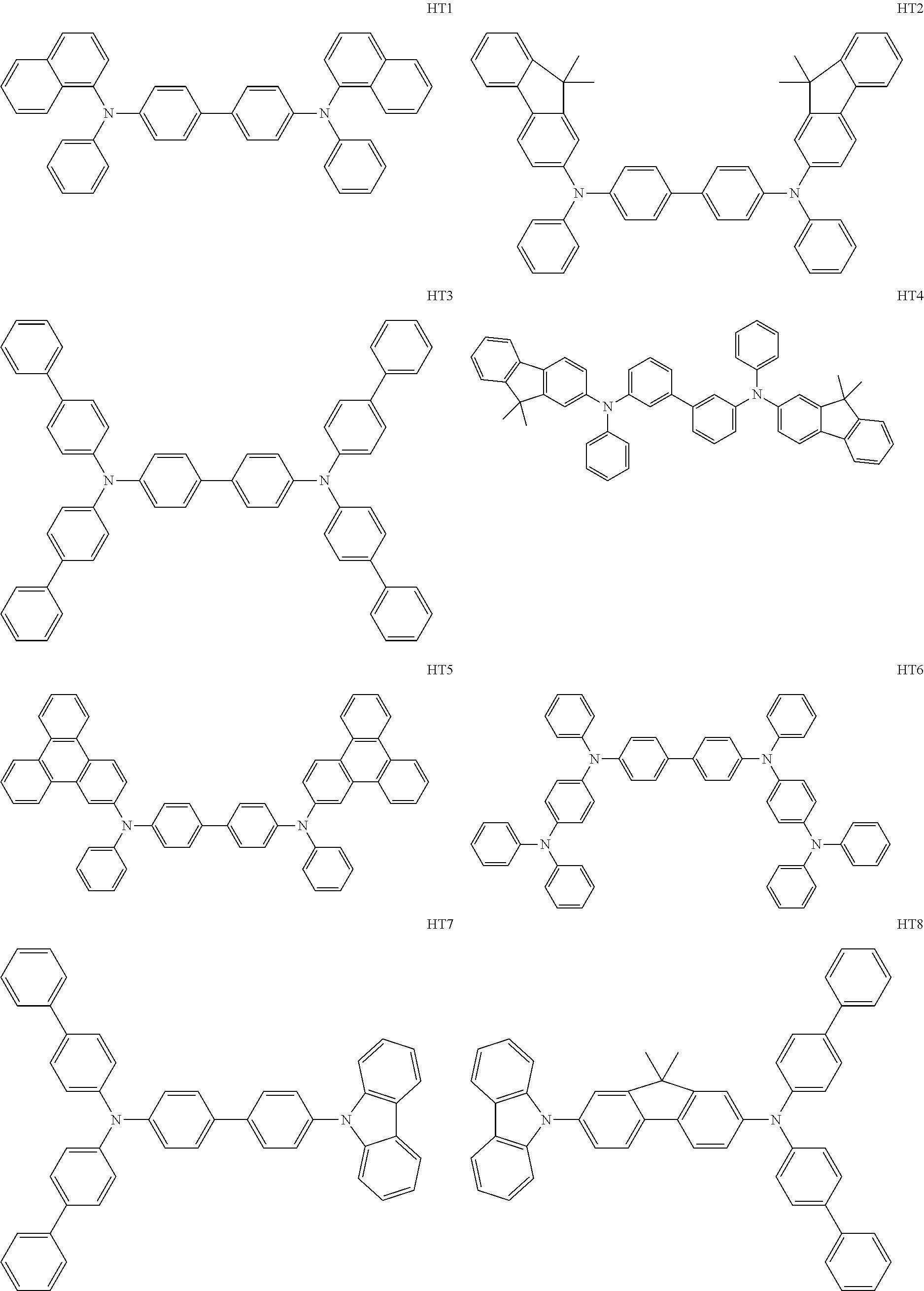

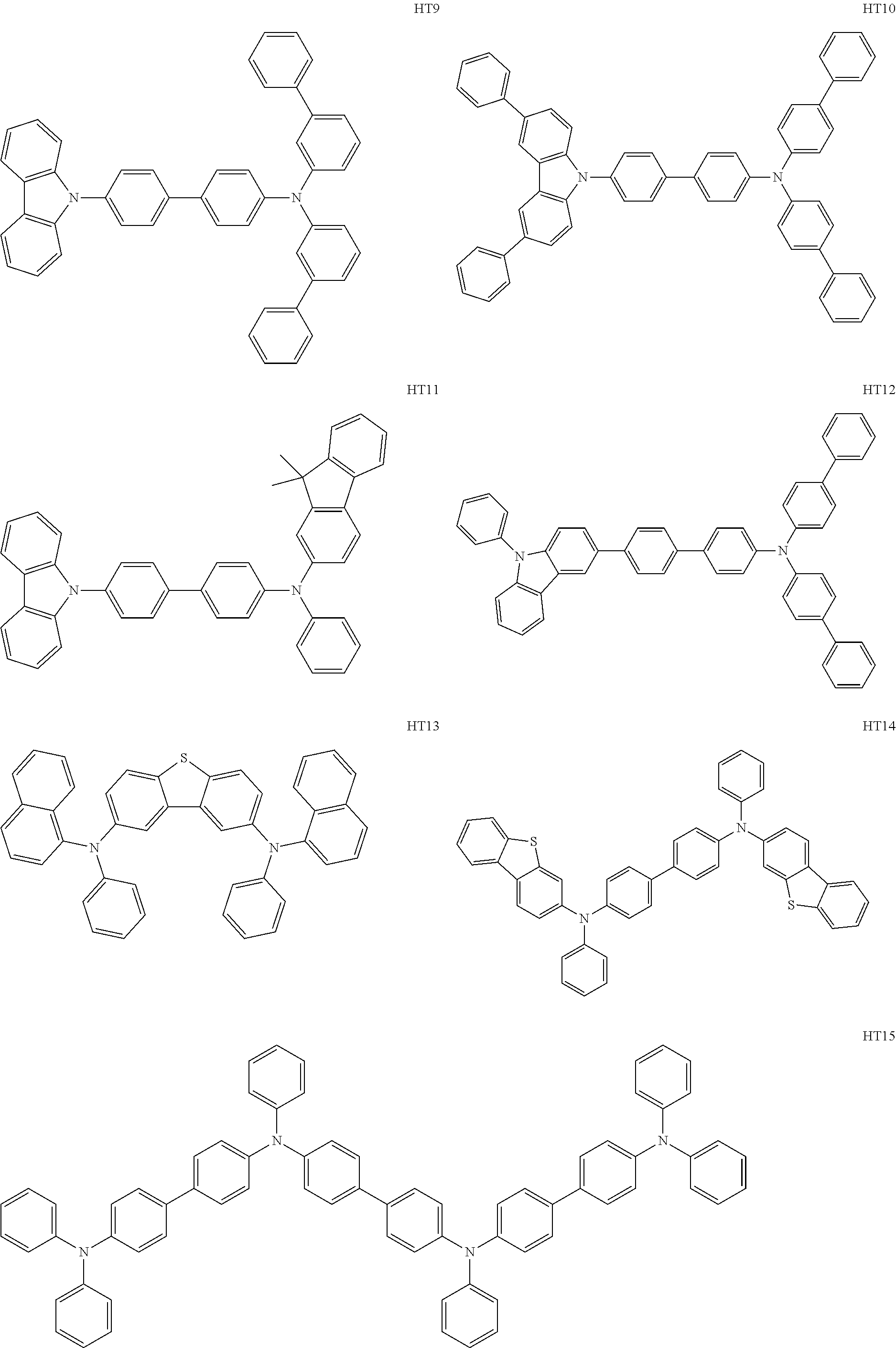

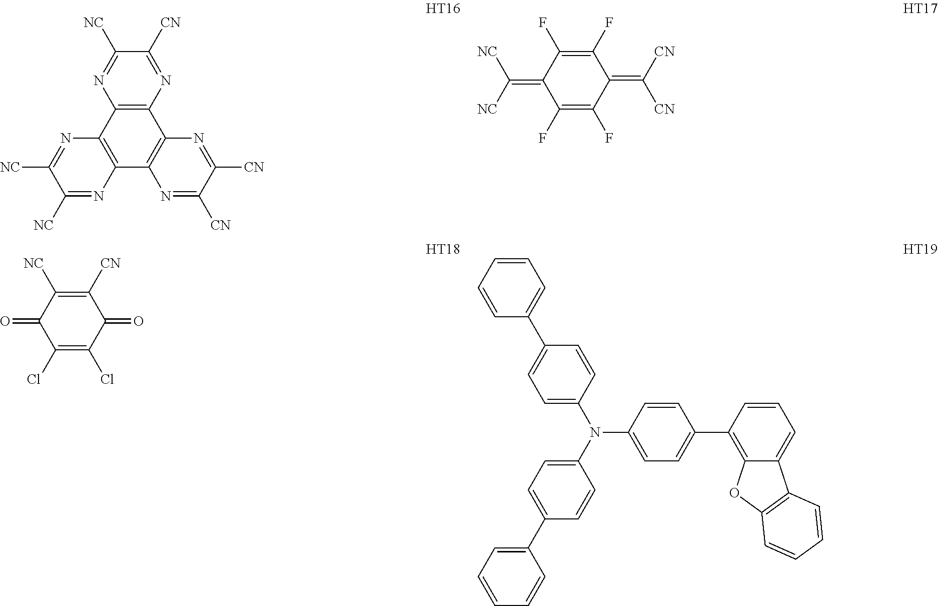

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

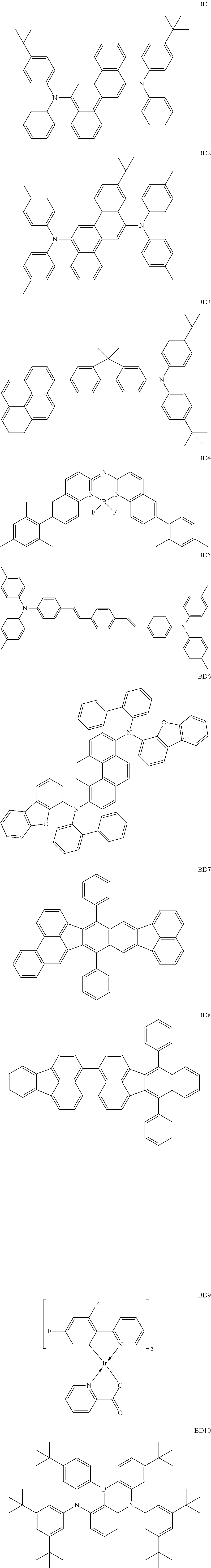

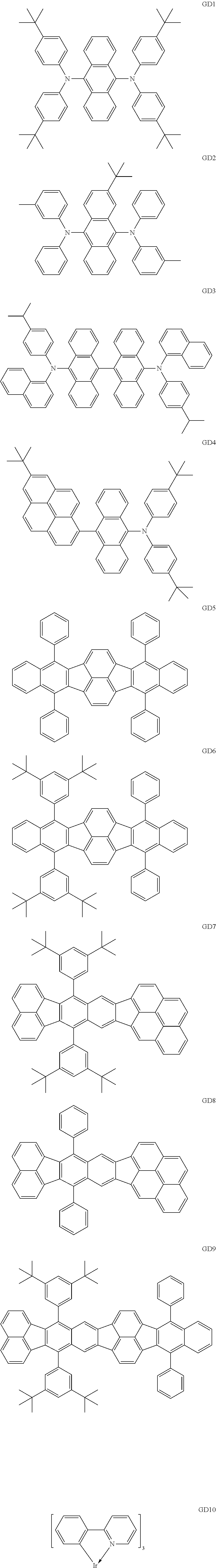

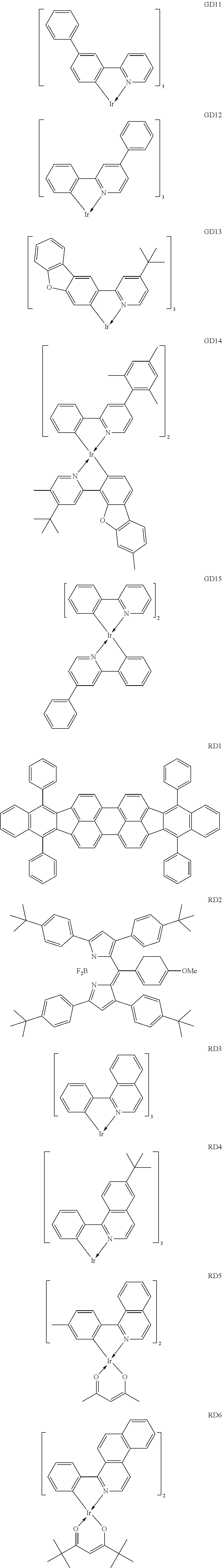

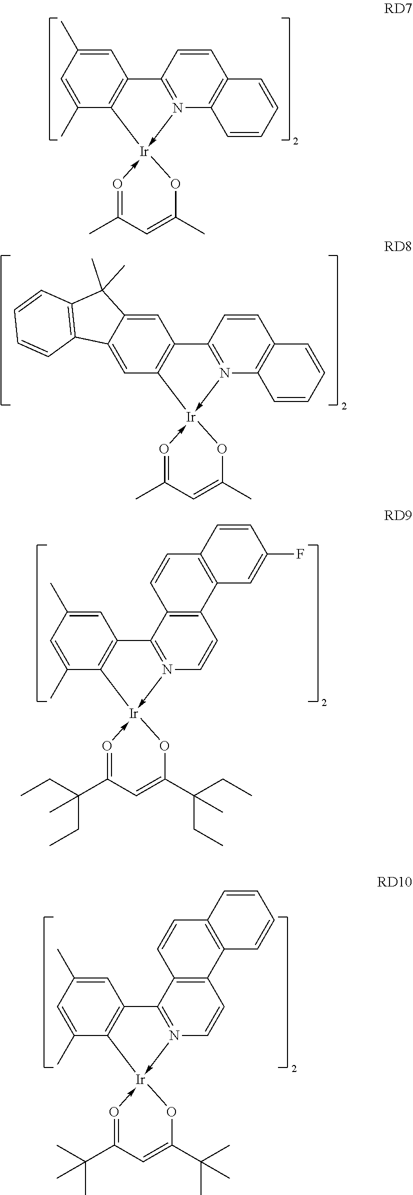

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

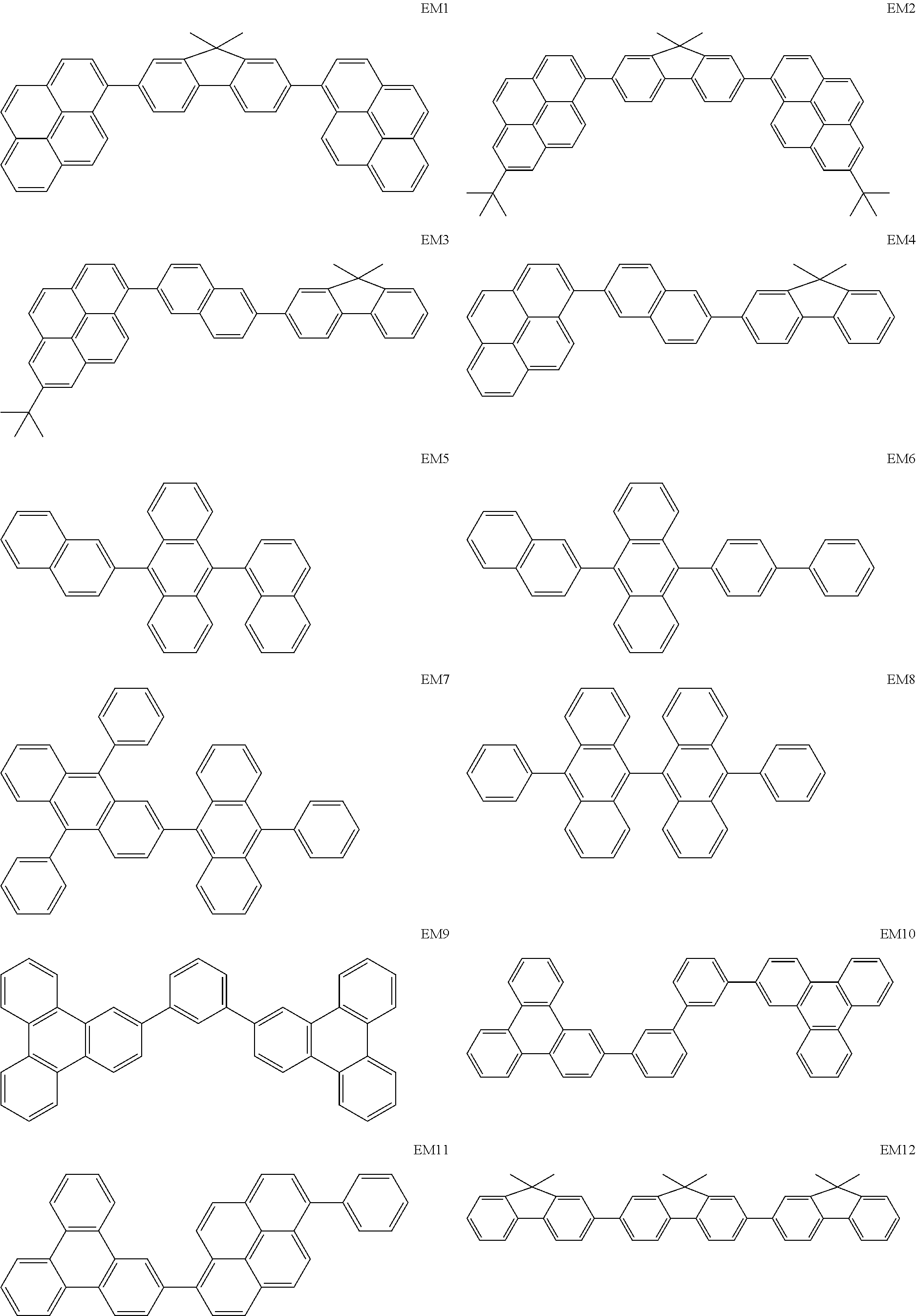

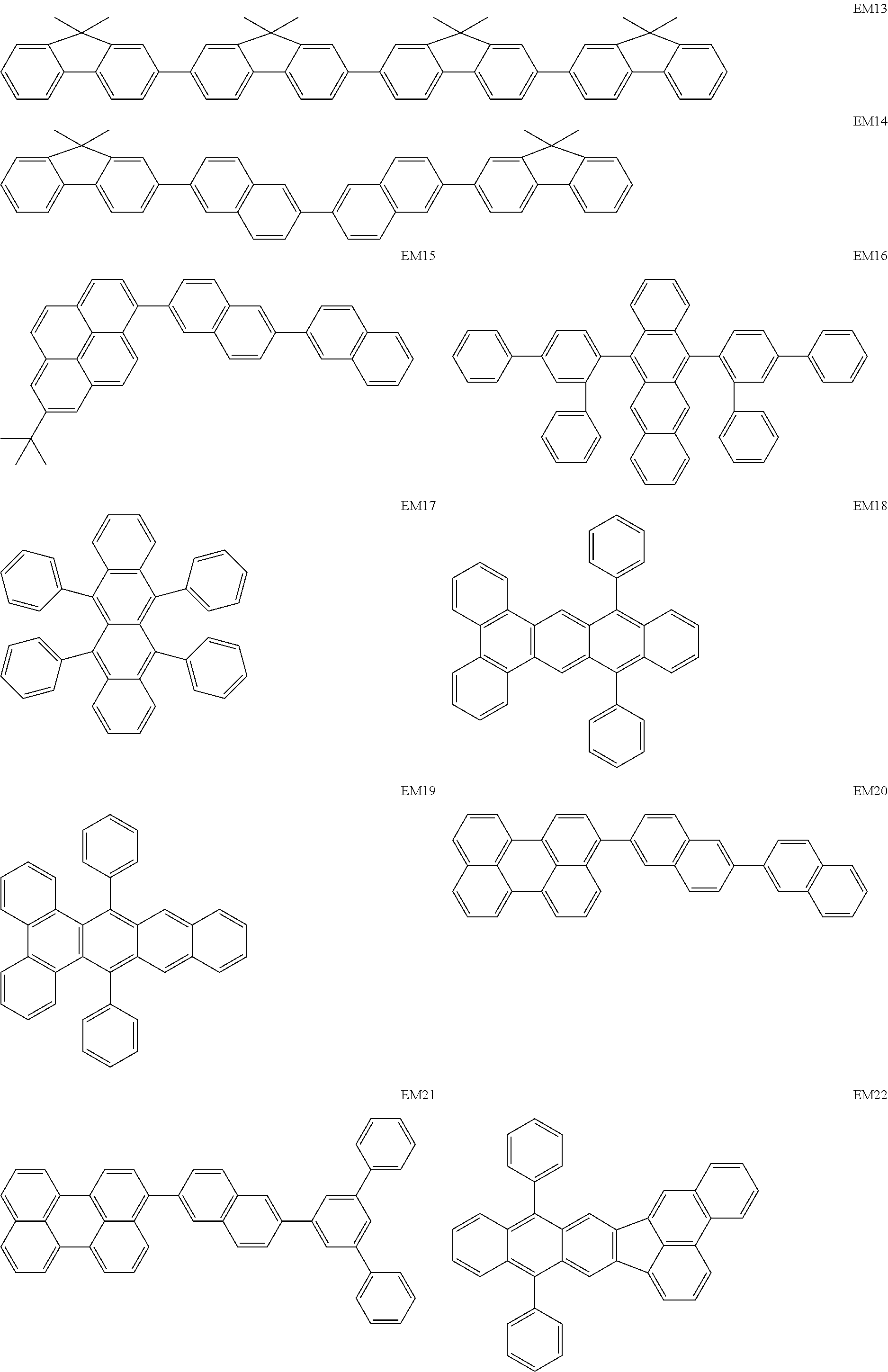

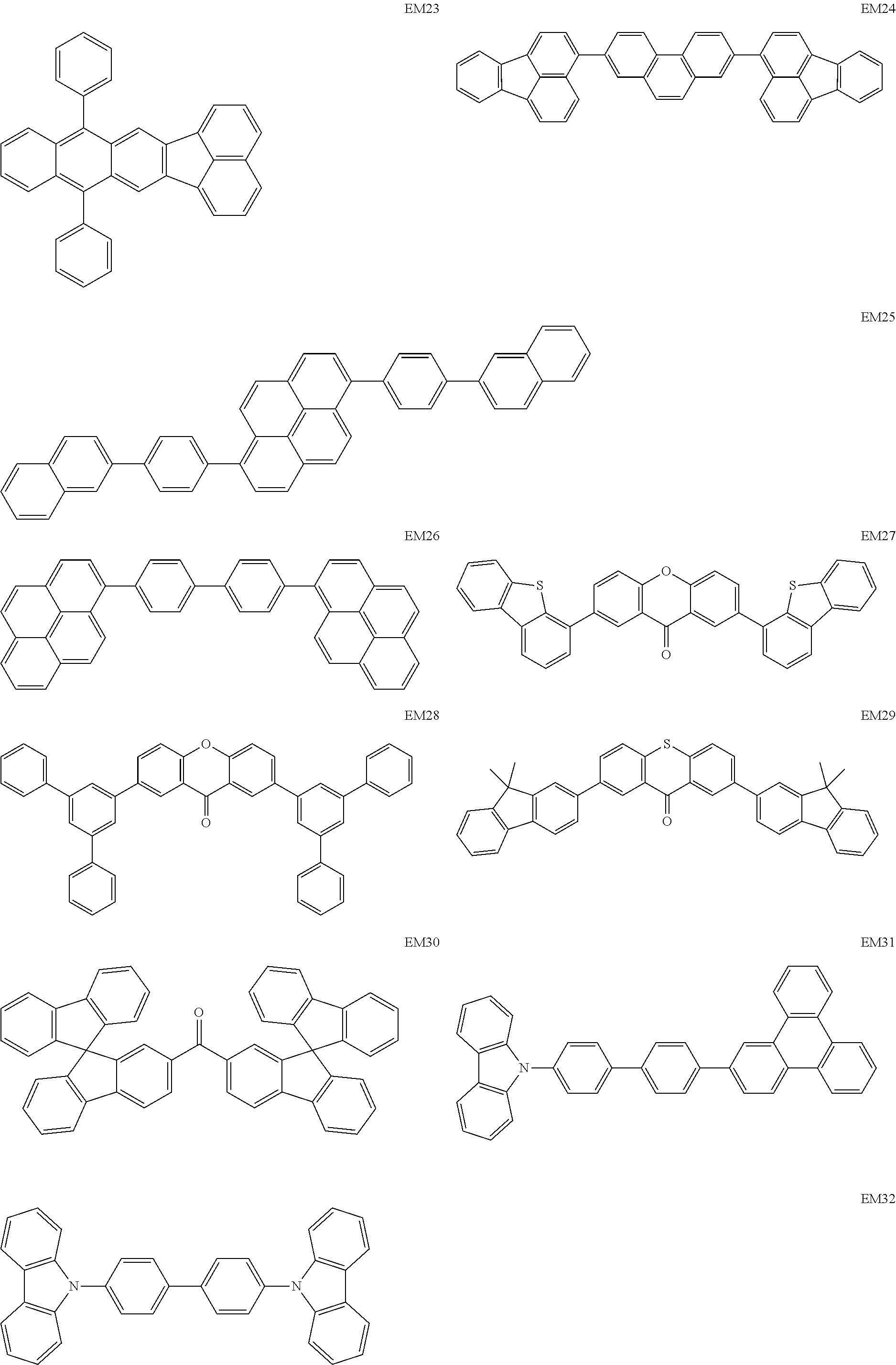

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material can also be used for the hole blocking layer as well.

Detailed examples of compounds used as the electron transport material will be shown below. The material is not limited to these.

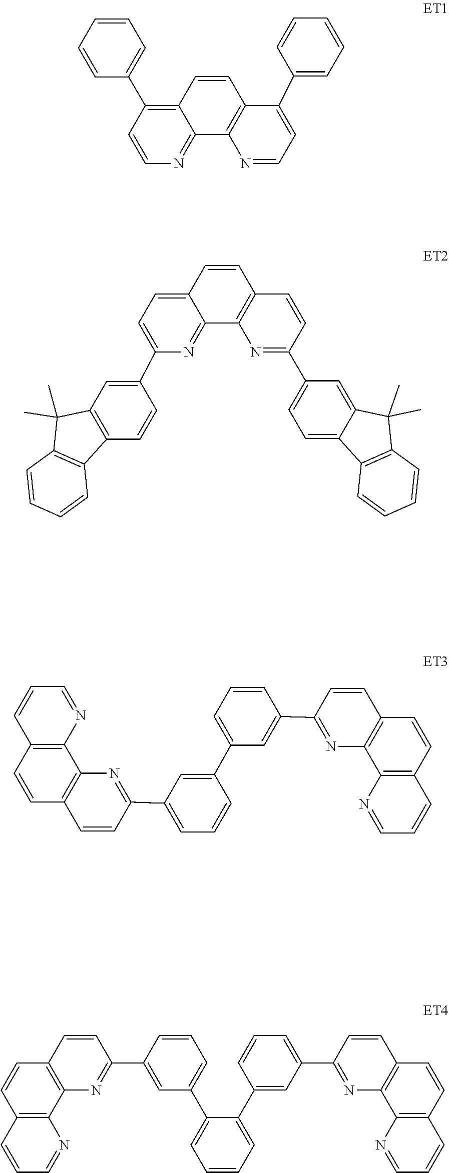

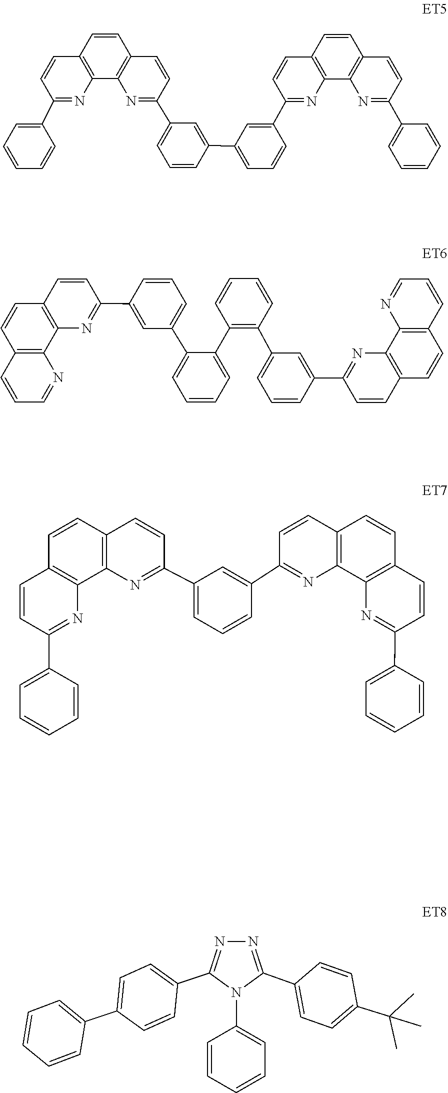 [SMILES: c1ccc(-c2ccc3ccc4ccc(-c5cccc(-c6cccc(-c7ccc8ccc9ccc(-c%10ccccc%10)nc9c8n7)c6)c5)nc4c3n2)cc1 ; c1cc(-c2ccc3ccc4cccnc4c3n2)cc(-c2ccccc2-c2ccccc2-c2cccc(-c3ccc4ccc5cccnc5c4n3)c2)c1 ; c1ccc(-c2ccc3ccc4ccc(-c5cccc(-c6ccc7ccc8ccc(-c9ccccc9)nc8c7n6)c5)nc4c3n2)cc1 ; CC(C)(C)c1ccc(-c2nnc(-c3ccc(-c4ccccc4)cc3)n2-c2ccccc2)cc1]

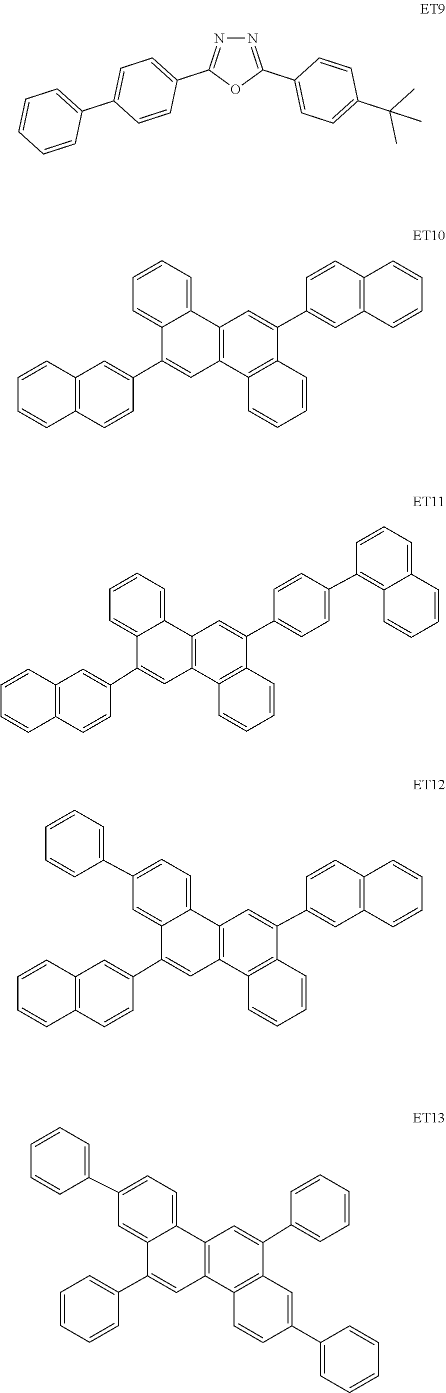

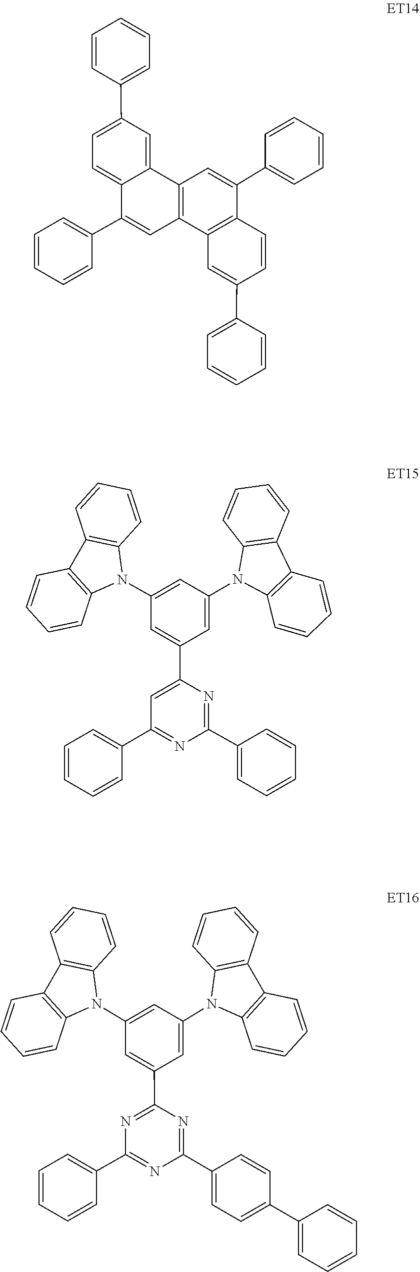

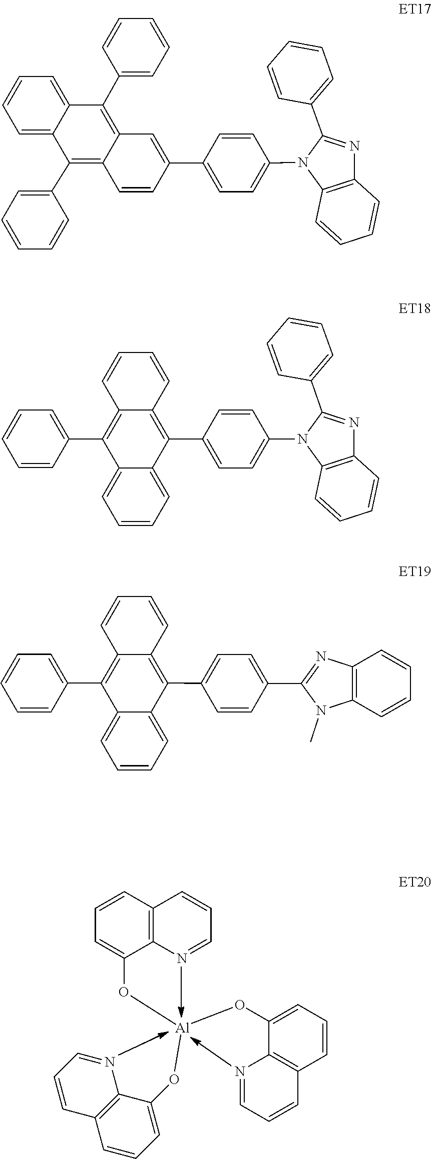

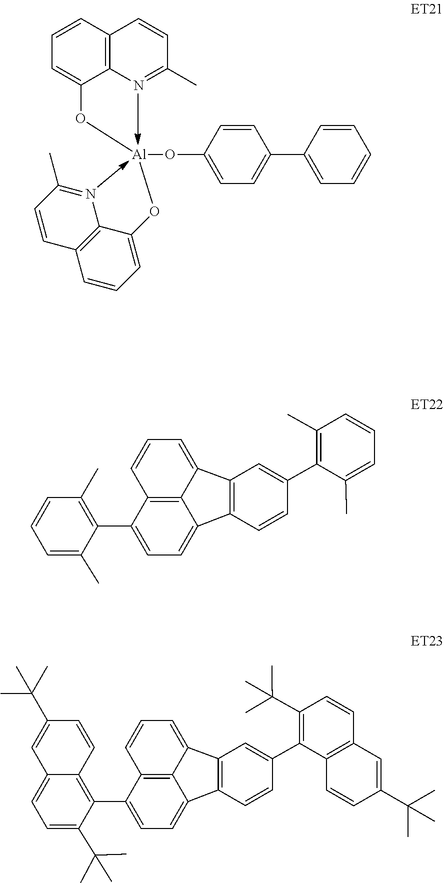

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generation portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known configuration form in a plan view. For example, the pixels may have a stripe configuration, a delta configuration, a pentile configuration, or a Bayer configuration. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel configuration can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 13A shows an example of the pixel arranged in the light emitting device. The pixel includes sub-pixels 810 (light emitting elements). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display device 800 (light emitting device) shown in FIG. 13B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 13B. That is, one of the anode and cathode and one of the source electrode and drain electrode of the TFT are electrically connected. The TFT indicates a thin-film transistor.

In the display device 800 shown in FIG. 13B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 13B, but another switching element may be used instead.

The transistor used in the display device 800 shown in FIG. 13B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 13B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

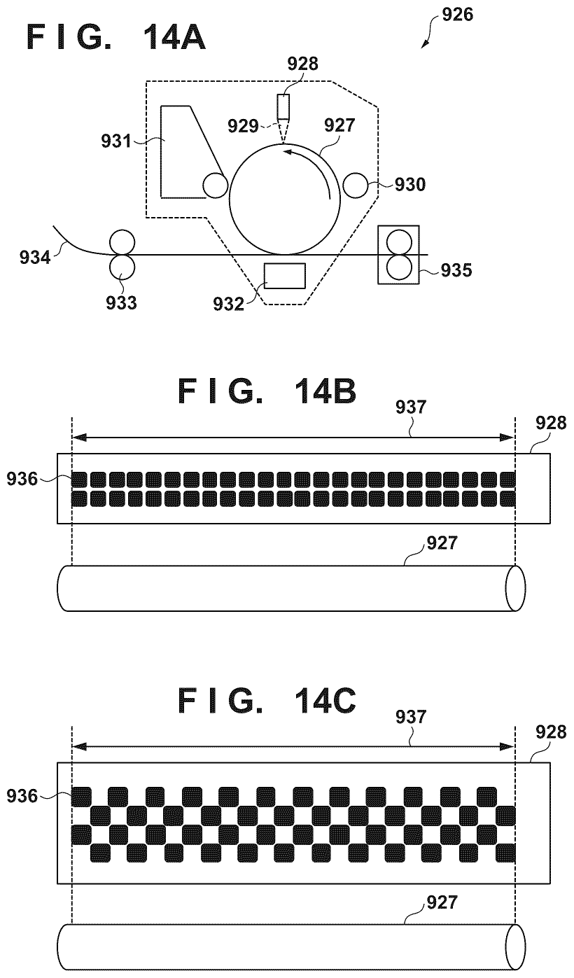

FIGS. 14A to 14C are schematic views showing an example of an image forming device using the light emitting device. An image forming device 926 shown in FIG. 14A includes a photosensitive member 927, an exposure light source 928, a developing unit 931, a charging unit 930, a transfer device 932, a conveyance unit 933 (a conveyance roller in the configuration shown in FIG. 14A), and a fixing device 935.

Light 929 is emitted from the exposure light source 928, and an electrostatic latent image is formed on the surface of the photosensitive member 927. The light emitting device can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 14B and 14C is a schematic view showing a form in which a plurality of light emitting units 936 are arranged in the exposure light source 928 along the longitudinal direction of a long substrate. The light emitting device can be applied to each of the light emitting units 936. That is, a plurality of the pixels (light emitting elements) are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 14B shows a form in which the light emitting units 936 are arranged along the long-axis direction of the photosensitive member 927. FIG. 14C shows a form, which is a modification of the configuration of the light emitting units 936 shown in FIG. 14B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The configuration of the light emitting units 936 shown in FIG. 14C can be referred to as, for example, an configuration in a grid pattern, an configuration in a staggered pattern, or an configuration in a checkered pattern.

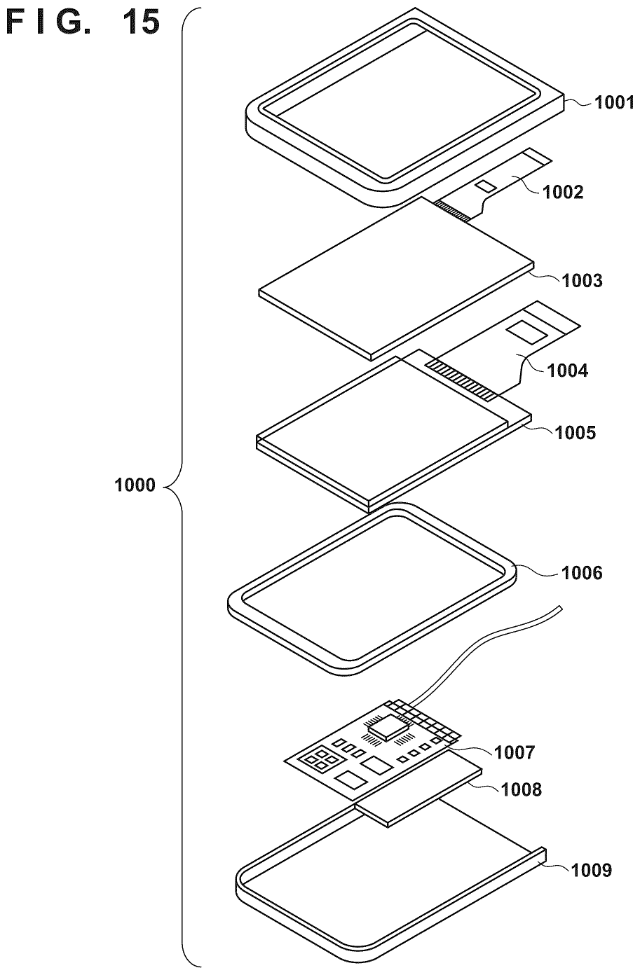

FIG. 15 is a schematic view showing an example of the display device using the light emitting device. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. A control circuit including a logic circuit formed from transistors and the like is arranged on the circuit board 1007. The battery 1008 is unnecessary if the display device 1000 is not a portable apparatus. Even when the display device 1000 is a portable apparatus, the battery 1008 need not be provided at this position. The light emitting device can be applied to the display panel 1005. The pixels (light emitting elements) arranged in the light emitting device functioning as the display panel 1005 are connected to the control circuit arranged on the circuit board 1007 and operate.

The display device 1000 shown in FIG. 15 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

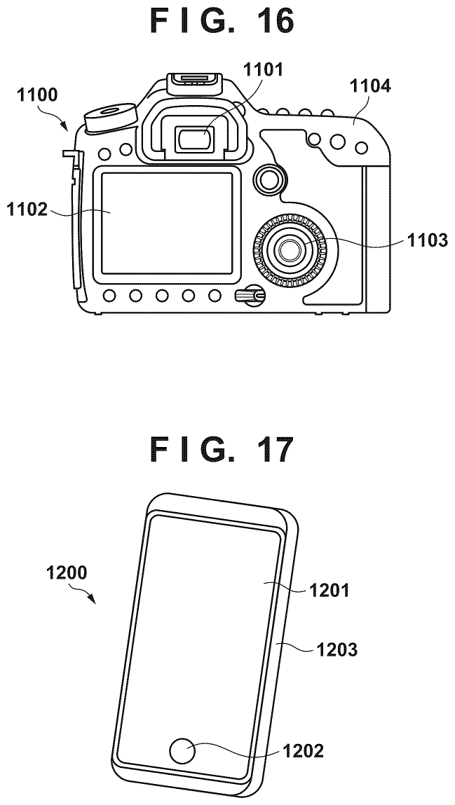

FIG. 16 is a schematic view showing an example of the photoelectric conversion device using the light emitting device. A photoelectric conversion device 1100 can include a viewfinder 1101, a rear display 1102, an operation unit 1103, and a housing 1104. The photoelectric conversion device 1100 can also be called an image capturing device. The light emitting device can be applied to the viewfinder 1101 or the rear display 1102 as a display unit. In this case, the light emitting device can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device in which the pixel (light emitting element) including the light emitting element using the organic light emitting material such as an organic EL element is arranged may be used for the viewfinder 1101 or the rear display 1102. This is so because the organic light emitting material has a high response speed. The light emitting device using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device may be applied to a display unit of an electronic apparatus. At this time, the display unit can have both a display function and an operation function. Examples of the portable terminal are a portable phone such as a smartphone, a tablet, and a head mounted display.

FIG. 17 is a schematic view showing an example of an electronic apparatus using the light emitting device according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device can be applied to the display unit 1201.

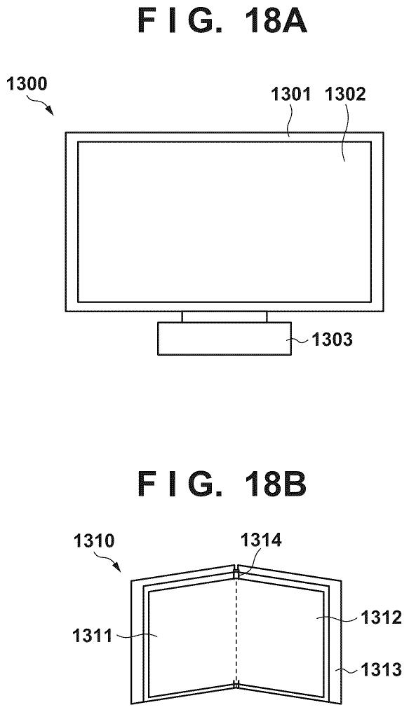

FIGS. 18A and 18B are schematic views showing examples of the display device using the light emitting device. FIG. 18A shows a display device such as a television monitor or a PC monitor. A display device 1300 includes a frame 1301 and a display unit 1302. The light emitting device can be applied to the display unit 1302. The display device 1300 can include a base 1303 that supports the frame 1301 and the display unit 1302. The base 1303 is not limited to the form shown in FIG. 18A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 18B is a schematic view showing another example of the display device using the light emitting device. A display device 1310 shown in FIG. 18B can be folded, and is a so-called foldable display device. The display device 1310 includes a first display unit 1311, a second display unit 1312, a housing 1313, and a bending point 1314. The light emitting device can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

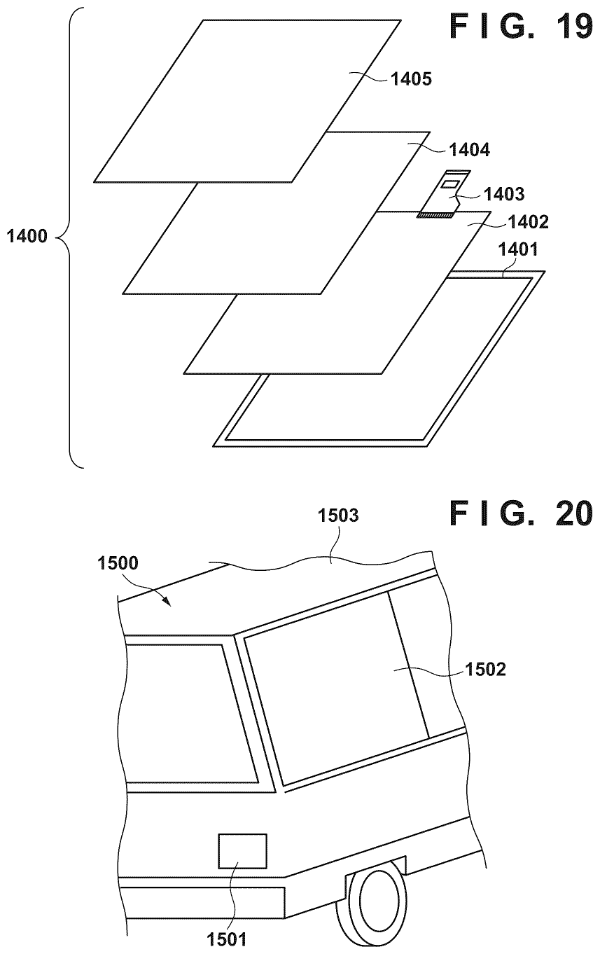

FIG. 19 is a schematic view showing an example of the illumination device using the light emitting device. An illumination device 1400 can include a housing 1401, a light source 1402, a circuit board 1403, an optical film 1404, and a light diffusing unit 1405. The light emitting device can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 20 is a schematic view of an automobile having a taillight as an example of a vehicle lighting appliance using the light emitting device. An automobile 1500 has a taillight 1501, and can have a form in which the taillight 1501 is turned on when performing a braking operation or the like. The light emitting device can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device can be applied to the taillight 1501. The taillight 1501 can include a protection member for protecting the light emitting device functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device may be used. In this case, the constituent materials of the electrodes and the like of the light emitting device are formed by transparent members.

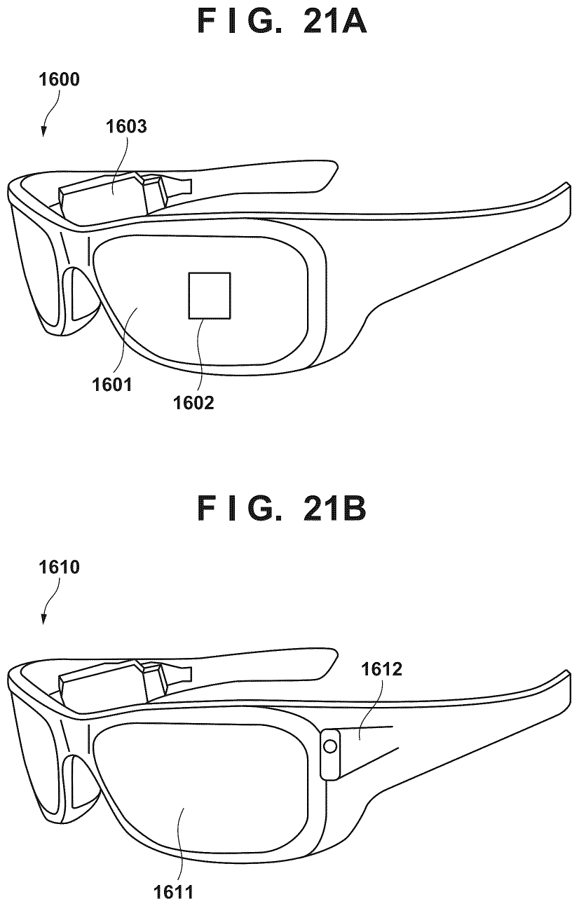

Further application examples of the light emitting device will be described with reference to FIGS. 21A and 21B. The light emitting device can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 21A. An image capturing device 1602 such as a CMOS sensor or an SPAD is provided on the surface side of a lens 1601 of the glasses 1600. In addition, the light emitting device is provided on the back surface side of the lens 1601.

The glasses 1600 further include a control device 1603. The control device 1603 functions as a power supply that supplies electric power to the image capturing device 1602 and the light emitting device. In addition, the control device 1603 controls the operations of the image capturing device 1602 and the light emitting device. An optical system configured to condense light to the image capturing device 1602 is formed on the lens 1601.

Glasses 1610 (smartglasses) according to one application example will be described with reference to FIG. 21B. The glasses 1610 include a control device 1612, and an image capturing device corresponding to the image capturing device 1602 and the light emitting device are mounted on the control device 1612. The image capturing device in the control device 1612 and an optical system configured to project light emitted from the light emitting device are formed in a lens 1611, and an image is projected to the lens 1611. The control device 1612 functions as a power supply that supplies electric power to the image capturing device and the light emitting device, and controls the operations of the image capturing device and the light emitting device. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device can include an image capturing device including a light receiving element, and control a displayed image based on the line-of-sight information of the user from the image capturing device. More specifically, the light emitting device decides a first visual field region at which the user is gazing and a second visual field region other than the first visual field region based on the line-of-sight information. The first visual field region and the second visual field region may be decided by the control device of the light emitting device, or those decided by an external control device may be received. In the display region of the light emitting device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device, the image capturing device, or an external device. If the external device holds the AI program, it is transmitted to the light emitting device via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-060404, filed Apr. 3, 2024, which is hereby incorporated by reference herein in its entirety.

What is claimed is:

1. A vapor deposition apparatus comprising:
an electrostatic chuck table having a holding surface configured to hold a vapor deposition target substrate; and
a contact portion configured to cause a mask to be in contact with the vapor deposition target substrate,
wherein the holding surface has a concave curved surface with a concave center.

2. The vapor deposition apparatus according to claim 1, wherein, in a sectional view in a direction intersecting the holding surface, the holding surface has an arc shape.

3. The vapor deposition apparatus according to claim 1, wherein the holding surface is a part of a spherical surface.

4. The vapor deposition apparatus according to claim 1, wherein the holding surface has a radius of curvature of not less than 25 m and not more than 500 m.

5. The vapor deposition apparatus according to claim 1, wherein the holding surface is circular in a planar view with respect to the holding surface.

6. The vapor deposition apparatus according to claim 1, wherein the electrostatic chuck table is configured such that a force per unit area for attracting the vapor deposition target substrate is greater in a central portion of the holding surface than in an outer edge portion thereof.

7. The vapor deposition apparatus according to claim 1, wherein the mask includes a plurality of first regions each having a first thickness and arranged with a plurality of opening portions, and a second region having a second thickness larger than the first thickness and arranged between adjacent first regions of the plurality of first regions.

8. The vapor deposition apparatus according to claim 7, wherein the second region is arranged in a grid pattern.

9. The vapor deposition apparatus according to claim 7, wherein
the mask includes a magnetic material layer arranged in the second region, and
the contact portion includes a magnet that attracts the magnetic material layer in a direction toward the holding surface.

10. The vapor deposition apparatus according to claim 9, wherein
the mask includes a contact layer arranged to cover the magnetic material layer, and
the contact layer has a lower hardness than the magnetic material layer.

11. The vapor deposition apparatus according to claim 7, wherein the first region is formed of a material having a volume magnetic susceptibility of not more than 1.

12. The vapor deposition apparatus according to claim 1, wherein the mask contains silicon as a base material.

13. The vapor deposition apparatus according to claim 12, wherein the mask includes a stress adjustment layer configured to impart a tensile stress to the base material.

14. The vapor deposition apparatus according to claim 1, wherein
the mask is formed of a magnetic material, and
the contact portion includes a magnet that attracts the mask in a direction toward the holding surface.

15. The vapor deposition apparatus according to claim 1, wherein the mask has a circular outer shape.

16. A manufacturing method of a light emitting device in which a plurality of pixels each including an organic layer including a light emitting layer are arranged in a substrate, the method comprising:
holding the substrate on a holding surface of an electrostatic chuck table;
arranging a mask to face the substrate and causing the mask to be in contact with the substrate; and
vapor-depositing the organic layer on the substrate via the mask,
wherein the holding surface has a concave curved surface with a concave center.
